(19) United States
(12) Patent Application Publication
(10) Pub. No.: US 2026/0344186 A1
(43) Pub. Date: Oct. 29, 2026

(54) THIN-FILM TRANSISTOR AND MANUFACTURING METHOD THEREOF, ARRAY SUBSTRATE AND DISPLAY DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Dacheng ZHANG, Beijing (CN); Jingbo XU, Beijing (CN); Ming WANG, Beijing (CN)

(21) Appl. No.: 19/688,367

(22) Filed: May 26, 2026

Related U.S. Application Data
(63) Continuation of application No. 18/558,261, filed on Sep. 23, 2022.

(51) Int. Cl. H10K 59/121; H10K 59/12

(52) U.S. Cl. CPC H10K 59/1213; H10K 59/1201

(57) ABSTRACT

A thin-film transistor includes an active layer and an electrode layer; the active layer includes a channel region, and first and second regions located at two sides of the channel region in a first direction; the electrode layer includes a gate electrode, a first electrode, and a second electrode; the first region includes a first lap region and a first transmission region, an orthographic projection of the first electrode on the active layer overlaps with the first lap region, the first transmission region includes at least one arc-shaped conductive structure each including a hollow part and a thinning portion at least partially surrounding the hollow part, a thickness of the thinning portion is smaller than a thickness of the active layer in the channel region, and the thinning portion is located at a side of the hollow part close to the edge.

### CROSS-REFERENCE TO RELATED APPLICATIONS

The present application is a continuation of U.S. application Ser. No. 18/558,261 filed on Oct. 31, 2023, which is a national stage application of international application PCT/CN 2022/120923 filed on Sep. 23, 2022. The entire contents of the above-mentioned applications are hereby incorporated by reference as a part of the present application.

### TECHNICAL FIELD

Embodiments of the present disclosure relate to a thin-film transistor and a manufacturing method thereof, an array substrate and a display device.

### BACKGROUND

With the continuous development of technology, display technology has been widely used in various electronic products, for example, small electronic products such as smart bracelets, smart watches, smart phones and tablet computers, and large electronic products such as laptops, desktop computers, on-board electrodes, navigators and TV sets. Therefore, the market's pursuit of the quality and cost efficiency of display devices is getting higher and higher.

Typically, the display device includes an array substrate provided with a pixel driving circuit, and the pixel driving circuit includes a plurality of thin-film transistors. Therefore, the performance of the thin-film transistors will greatly affect the quality and service life of the entire display device.

### SUMMARY

Embodiments of the present disclosure discloses a thin-film transistor and a manufacturing method thereof, an array substrate and a display device. By arranging at least one arc-shaped conductive structure in the first transmission region of the thin-film transistor, a stable conductive channel is formed between the first lap region and the first transmission region, thereby enhancing the conductivity of the thin-film transistor.

At least one embodiment of the present disclosure provides a thin-film transistor including an active layer including a channel region, and a first region and a second region located at two sides of the channel region in a first direction; and an electrode layer including a gate electrode, a first electrode, and a second electrode, wherein the first region includes a first lap region and a first transmission region, an orthographic projection of the first electrode on the active layer overlaps with the first lap region, the first transmission region includes at least one arc-shaped conductive structure, each of the at least one arc-shaped conductive structure includes a hollow part and a thinning portion at least partially surrounding the hollow part, a thickness of the thinning portion is smaller than a thickness of the active layer in the channel region, one arc-shaped conductive structure is connected to one edge of the first lap region, a size of an orthographic projection of the arc-shaped conductive structure on the edge is smaller than a length of the edge, and the thinning portion is located at a side of the hollow part close to the edge.

For example, in the thin-film transistor provided in an embodiment of the present disclosure, the at least one arc-shaped conductive structure includes a first arc-shaped conductive structure, the first arc-shaped conductive structure includes a first hollow part and a first thinning portion at least partially surrounding the first hollow part, a thickness of the first thinning portion is smaller than the thickness of the active layer in the channel region, the first lap region includes a first edge extending in a second direction, the first edge and an edge of the channel region are disposed opposite to each other at an interval, the first arc-shaped conductive structure is connected to the first edge, and a size of the first arc-shaped conductive structure in the second direction is smaller than a length of the first edge, and the second direction intersects with the first direction.

For example, in the thin-film transistor provided in an embodiment of the present disclosure, the at least one arc-shaped conductive structure includes at least two first arc-shaped conductive structures, the first lap region includes a first doped region and a first functional region, the first functional region is connected to the first edge and is located between two first arc-shaped conductive structures in the second direction.

For example, in the thin-film transistor provided in an embodiment of the present disclosure, a distance between two first arc-shaped conductive structures is greater than a size of each of the two first arc-shaped conductive structures in the first direction, and is smaller than a size of the active layer in the second direction.

For example, in the thin-film transistor provided in an embodiment of the present disclosure, the at least one arc-shaped conductive structure further includes at least two second arc-shaped conductive structures, each of the at least two second arc-shaped conductive structures includes a second hollow part and a second thinning portion at least partially surrounding the second hollow part, a thickness of the second thinning portion is smaller than the thickness of the active layer in the channel region, the first lap region further includes a second edge, the second edge is connected to the first edge, the first lap region further includes a second functional region, the second functional region is connected to the second edge and is located between two second arc-shaped conductive structures in the first direction, the second arc-shaped conductive structure is connected to the second edge, and a size of the second arc-shaped conductive structure in the first direction is smaller than a length of the second edge.

For example, in the thin-film transistor provided in an embodiment of the present disclosure, the at least one arc-shaped conductive structure further includes at least two third arc-shaped conductive structures, each of the at least two third arc-shaped conductive structures includes a third hollow part and a third thinning portion at least partially surrounding the third hollow part, a thickness of the third thinning portion is smaller than the thickness of the active layer in the channel region, the first lap region further includes a third edge, the third edge is connected to the first edge, and the third edge and the second edge are disposed opposite to each other at an interval, the first lap region further includes a third functional region, the third functional region is connected to the third edge and is located between two third arc-shaped conductive structures in the first direction, the third arc-shaped conductive structure is connected to the third edge, and a size of the third arc-shaped conductive structure in the first direction is smaller than a length of the third edge.

For example, in the thin-film transistor provided in an embodiment of the present disclosure, a first distance is provided between the first functional region and the second functional region, a second distance is provided between the second functional region and the third functional region, and a third distance is provided between the third functional region and the first functional region, the first distance, the second distance, and the third distance are all greater than a width of the first electrode in the second direction.

For example, in the thin-film transistor provided in an embodiment of the present disclosure, an orthographic projection of the second functional region on a reference line extending in the first direction and an orthographic projection of the third functional region on the reference line are spaced apart from each other.

For example, in the thin-film transistor provided in an embodiment of the present disclosure, a distance between the orthographic projection of the second functional region on the reference line and the orthographic projection of the third functional region on the reference line is greater than a distance between two adjacent second arc-shaped conductive structures in the first direction.

For example, in the thin-film transistor provided in an embodiment of the present disclosure, a distance between the second functional region and the third functional region is greater than a width of the channel region in the first direction.

For example, in the thin-film transistor provided in an embodiment of the present disclosure, the first electrode includes a protrusion portion and an extension portion, the extension portion is located at a side of the protrusion portion away from the channel region, and a size of the protrusion portion in the second direction is greater than a size of the extension portion in the second direction, the size of the protrusion portion in the second direction is greater than a sum of s size of the second functional region in the second direction and a size of the third functional region in the second direction.

For example, in the thin-film transistor provided in an embodiment of the present disclosure, the first functional region, the second functional region, and the third functional region are all un-doped regions.

For example, in the thin-film transistor provided in an embodiment of the present disclosure, the first functional region, the second functional region, and the third functional region are all semi-doped regions.

For example, in the thin-film transistor provided in an embodiment of the present disclosure, a size of the first functional region in the second direction is smaller than a size of the first doped region in the second direction, an area of the first functional region is smaller than an area of the channel region, and the area of the first functional region is smaller than an area of the first hollow part.

For example, in the thin-film transistor provided in an embodiment of the present disclosure, the first lap region further includes a first semiconductor region located at two sides of the first doped region in the second direction, an area of the first functional region is smaller than an area of the first semiconductor region.

For example, in the thin-film transistor provided in an embodiment of the present disclosure, the active layer has a first thickness a in the channel region, the active layer has a second thickness b in the first doped region, the active layer has a third thickness c in the first functional region, the first thinning portion has a fourth thickness d, and the active layer has a fifth thickness e in the first transmission region, the first thickness a, the second thickness b, the third thickness c, the fourth thickness d and the fifth thickness e satisfy the following formula:

a>c>b=e>d.

For example, in the thin-film transistor provided in an embodiment of the present disclosure, the second region includes a second lap region and a second transmission region, an orthographic projection of the second electrode on the active layer overlaps with the second lap region, the second transmission region includes a fourth arc-shaped conductive structure, each fourth arc-shaped conductive structure includes a fourth hollow part and a fourth thinning portion at least partially surrounding the fourth hollow part, a thickness of the fourth thinning portion is smaller than the thickness of the active layer in the channel region, the second lap region includes a fourth edge extending along a third direction, the fourth edge and an edge of the channel region are disposed opposite to each other at an interval, the fourth arc-shaped conductive structure is connected to the fourth edge, and a size of the fourth arc-shaped conductive structure in the third direction is smaller than a length of the fourth edge, and the third direction intersects with the first direction.

For example, in the thin-film transistor provided in an embodiment of the present disclosure, the second transmission region includes at least two fourth arc-shaped conductive structures, the second lap region includes a second doped region and a fourth functional region, the fourth functional region is connected to the fourth edge and is located between two fourth arc-shaped conductive structures in the third direction.

For example, in the thin-film transistor provided in an embodiment of the present disclosure, the second transmission region further includes at least two fifth arc-shaped conductive structures, each of the at least two fifth arc-shaped conductive structures includes a fifth hollow part and a fifth thinning portion at least partially surrounding the fifth hollow part, a thickness of the fifth thinning portion is smaller than the thickness of the active layer in the channel region, the second lap region further includes a fifth edge, the fifth edge is connected to the fourth edge, the second lap region further includes a fifth functional region, the fifth functional region is connected to the fifth edge and is located between two fifth arc-shaped conductive structures, the fifth arc-shaped conductive structure is connected to the fifth edge, and a size of the fifth arc-shaped conductive structure in the first direction is smaller than a length of the fifth edge.

For example, in the thin-film transistor provided in an embodiment of the present disclosure, the second transmission region further includes at least two sixth arc-shaped conductive structures, each of the at least two sixth arc-shaped conductive structures includes a sixth hollow part and a sixth thinning portion at least partially surrounding the sixth hollow part, a thickness of the sixth thinning portion is smaller than the thickness of the active layer in the channel region, the second lap region further includes a sixth edge, the sixth edge is connected to the fourth edge, and the sixth edge and the fifth edge are disposed opposite to each other at an interval, the second lap region further includes a sixth functional region, the sixth functional region is connected to the sixth edge and is located between two sixth arc-shaped conductive structures, the sixth arc-shaped conductive structure is connected to the sixth edge, and a size of the sixth arc-shaped conductive structure in the first direction is smaller than a length of the sixth edge.

For example, in the thin-film transistor provided in an embodiment of the present disclosure, a fourth distance is provided between the fourth functional region and the fifth functional region, a fifth distance is provided between the fifth functional region and the sixth functional region, and a sixth distance is provided between the sixth functional region and the fourth functional region, the fourth distance, the fifth distance, and the sixth distance are all greater than a width of the second electrode in the second direction.

For example, in the thin-film transistor provided in an embodiment of the present disclosure, an orthographic projection of the fifth functional region on a reference line extending in the first direction and an orthographic projection of the sixth functional region on the reference line are spaced apart from each other.

For example, in the thin-film transistor provided in an embodiment of the present disclosure, a distance between the orthographic projection of the fifth functional region on the reference line and the orthographic projection of the sixth functional region on the reference line is greater than a distance between two adjacent fifth arc-shaped conductive structures in the first direction.

For example, in the thin-film transistor provided in an embodiment of the present disclosure, a distance between the fifth functional region and the sixth functional region is greater than a width of the channel region in the first direction.

For example, in the thin-film transistor provided in an embodiment of the present disclosure, the fourth functional region, the fifth functional region, and the sixth functional region are all un-doped regions.

For example, in the thin-film transistor provided in an embodiment of the present disclosure, the fourth functional region, the fifth functional region, and the sixth functional region are all semi-doped regions.

For example, in the thin-film transistor provided in an embodiment of the present disclosure, the second direction and the third direction are parallel to each other.

For example, in the thin-film transistor provided in an embodiment of the present disclosure, an orthographic projection of the gate electrode on the active layer is located in the channel region, the first electrode is a source electrode, and the second electrode is a drain electrode.

For example, in the thin-film transistor provided in an embodiment of the present disclosure, the first lap region further includes a first strip-shaped conductive region located at the first edge, and the first strip-shaped conductive region and the first arc-shaped conductive structure are disposed sequentially in the second direction.

For example, in the thin-film transistor provided in an embodiment of the present disclosure, the second region includes a second lap region and a second transmission region, an orthographic projection of the second electrode on the active layer overlaps with the second lap region, the second transmission region includes a fourth arc-shaped conductive structure, each fourth arc-shaped conductive structure includes a fourth hollow part and a fourth thinning portion at least partially surrounding the fourth hollow part, a thickness of the fourth thinning portion is smaller than the thickness of the active layer in the channel region, the second lap region includes a fourth edge extending along a third direction, the fourth edge and an edge of the channel region are disposed opposite to each other at an interval, the fourth arc-shaped conductive structure is connected to the fourth edge, and a size of the fourth arc-shaped conductive structure in the third direction is smaller than a length of the fourth edge, and the third direction intersects with the first direction, the second lap region further includes a second strip-shaped conductive region located at the fourth edge, and the second strip-shaped conductive region and the fourth arc-shaped conductive structure are disposed sequentially in the third direction.

At least one embodiment of the present disclosure also provides an array substrate, including: a base substrate; and a plurality of pixel driving circuits located on the base substrate, wherein at least one of the plurality of pixel driving circuits includes the thin-film transistor described in any of the above.

For example, in the array substrate provided in an embodiment of the present disclosure, each of the plurality of pixel driving circuits includes: a first transistor including a gate electrode, a first electrode, and a second electrode; a second transistor including a gate electrode, a first electrode, and a second electrode; a third transistor including a gate electrode, a first electrode, and a second electrode, wherein the gate electrode of the first transistor is configured to be connected to a first gate line, the first electrode of the first transistor is configured to be connected to a data line, and the second electrode of the first transistor is connected to the gate electrode of the third transistor, the first electrode of the third transistor is configured to be connected to a power line, the gate electrode of the second transistor is configured to be connected to a second gate line, the first electrode of the second transistor is configured to be connected to a sensing line, and the second electrode of the second transistor is connected to the second electrode of the third transistor.

For example, in the array substrate provided in an embodiment of the present disclosure, the first transistor, the second transistor and the third transistor are all the thin-film transistors, a number of the arc-shaped conductive structure in the third transistor is greater than a number of the arc-shaped conductive structure in the second transistor, and is greater than a number of the arc-conductive structure in the first transistor.

For example, in the array substrate provided in an embodiment of the present disclosure, the first electrode of the third transistor is connected to an active layer of the third transistor through a first via hole, the first electrode of the first transistor is connected to an active layer of the first transistor through a second via hole, and the first electrode of the second transistor is connected to an active layer of the second transistor through a third via hole, an area of an orthographic projection of the first via hole on the base substrate is greater than an area of an orthographic projection of the second via hole on the base substrate, and is greater than an area of an orthographic projection of the third via hole on the base substrate.

At least one embodiment of the present disclosure also provides a display device, including the array substrate described in any of the above.

At least one embodiment of the present disclosure also provides a manufacturing method of a thin-film transistor, including: forming a semiconductor layer; performing a first time of conductorization process on the semiconductor layer; forming an electrode layer; performing a second time of conductorization process on the semiconductor layer by using the electrode layer as a mask to form an active layer including a channel region as well as a first region and a second region located at two sides of the channel region in a first direction, wherein the electrode layer includes a gate electrode, a first electrode, and a second electrode, the first region includes a first lap region and a first transmission region, an orthographic projection of the first electrode on the active layer overlaps with the first lap region, the first transmission region includes at least one arc-shaped conductive structure, each of the at least one arc-shaped conductive structure includes a hollow part and a thinning portion at least partially surrounding the hollow part, a thickness of the thinning portion is smaller than a thickness of the active layer in the channel region, one arc-shaped conductive structure is connected to one edge of the first lap region, a size of an orthographic projection of the arc-shaped conductive structure on the edge is smaller than a length of the edge, and the thinning portion is located at a side of the hollow part close to the edge.

At least one embodiment of the present disclosure also provides a thin-film transistor, including: an active layer including a channel region as well as a first region and a second region located at two sides of the channel region in a first direction; and an electrode layer including a gate electrode, a first electrode and a second electrode, wherein the first region includes a first lap region and a first transmission region, an orthographic projection of the first electrode on the active layer overlaps with the first lap region, the first lap region includes a first edge extending in a second direction, the first edge and an edge of the channel region are disposed opposite to each other at an interval, the first lap region includes a first doped region and a first functional region, the first functional region is connected to the first edge, and the first doped region is located at two sides of the first functional region in the second direction, respectively.

For example, in the thin-film transistor provided in an embodiment of the present disclosure, a thickness of the active layer in the first functional region is greater than a thickness of the active layer in the first doped region.

For example, in the thin-film transistor provided in an embodiment of the present disclosure, the first functional region is an un-doped region or a semi-doped region.

For example, in the thin-film transistor provided in an embodiment of the present disclosure, the first lap region further includes a second edge, the second edge is connected to the first edge, the first lap region further includes a second functional region, the second functional region is connected to the second edge, and the first doped region is located at two sides of the second functional region in the first direction, respectively.

For example, in the thin-film transistor provided in an embodiment of the present disclosure, the first lap region further includes a third edge, the third edge is connected to the first edge, and the third edge and the second edge are disposed opposite to each other at an interval, the first lap region further includes a third functional region, the third functional region is connected to the third edge, and the first doped region is located at two sides of the third functional region in the first direction, respectively.

### BRIEF DESCRIPTION OF THE DRAWINGS

In order to clearly illustrate the technical solution of the embodiments of the disclosure, the drawings of the embodiments will be briefly described in the following; it is apparent that the described drawings are only related to some embodiments of the disclosure and are not limitative of the disclosure.

FIG. 1 is a flow chart of a manufacturing method of an array substrate;

FIGS. 2A-2C are schematic cross-sectional views of an active layer having a loss in a manufacturing method of an array substrate;

FIGS. 3A-3C are schematic plan views of an active layer having a loss in a manufacturing method of an array substrate;

FIG. 4A is a schematic plan view of a thin-film transistor provided in an embodiment of the present disclosure;

FIG. 4B is a schematic cross-sectional view of a part of a thin-film transistor provided in an embodiment of the present disclosure;

FIGS. 5A-5C are schematic diagrams illustrating steps of a manufacturing method of a thin-film transistor provided in an embodiment of the present disclosure;

FIG. 6 is a schematic plan view of a thin-film transistor provided in an embodiment of the present disclosure;

FIGS. 7A-7C are schematic diagrams illustrating steps of a manufacturing method of a thin-film transistor provided in an embodiment of the present disclosure;

FIG. 8 is a schematic plan view of another thin-film transistor provided in an embodiment of the present disclosure;

FIG. 9 is a schematic plan view of a thin-film transistor provided in an embodiment of the present disclosure;

FIG. 10 is a schematic plan view of another thin-film transistor provided in an embodiment of the present disclosure;

FIGS. 11A-11C are schematic diagrams illustrating steps of a manufacturing method of a thin-film transistor provided in an embodiment of the present disclosure;

FIG. 12 is a schematic plan view of another thin-film transistor provided in an embodiment of the present disclosure;

FIGS. 13A-13C are schematic diagrams illustrating steps of a manufacturing method of a thin-film transistor provided in an embodiment of the present disclosure;

FIG. 14 is a schematic plan view of another thin-film transistor provided in an embodiment of the present disclosure;

FIG. 15 is a schematic plan view of an array substrate provided in an embodiment of the present disclosure;

FIG. 16 is a schematic equivalent diagram of a pixel driving circuit in an array substrate provided in an embodiment of the present disclosure;

FIG. 17 is a driving timing diagram of a pixel driving circuit in an array substrate provided in an embodiment of the present disclosure;

FIG. 18 is a schematic plan view of another array substrate provided in an embodiment of the present disclosure;

FIG. 19 is a schematic view of a display device provided in an embodiment of the present disclosure; and

FIG. 20 is a flow chart of a manufacturing method of a thin-film transistor provided in an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

In order to lower the manufacturing cost of the array substrate, it can reduce the number of masking processes for the array substrate. Therefore, by reasonably designing the layer structure(s) on the array substrate and reducing the number of the masking processes of some film layers, the manufacturing cost of the array substrate can be effectively reduced.

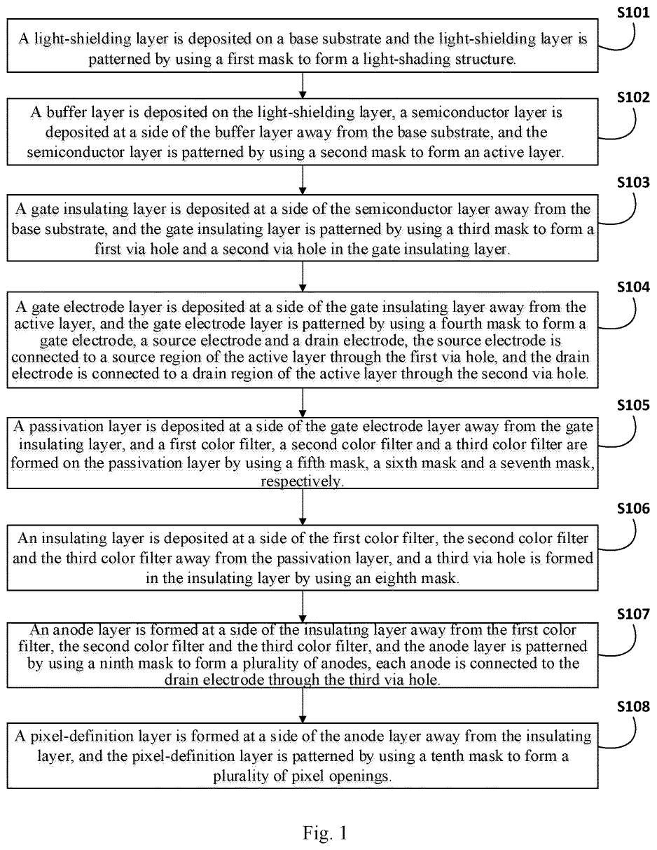

FIG. 1 shows a flow chart of a manufacturing method of an array substrate. As shown in FIG. 1, the manufacturing method of the array substrate includes the following steps S101-S108:

Step S101: a light-shielding layer is deposited on a base substrate and the light-shielding layer is patterned by using a first mask to form a light-shading structure.

Step S102: a buffer layer is deposited on the light-shielding layer, a semiconductor layer is deposited at a side of the buffer layer away from the base substrate, and the semiconductor layer is patterned by using a second mask to form an active layer.

Step S103: a gate insulating layer is deposited at a side of the semiconductor layer away from the base substrate, and the gate insulating layer is patterned by using a third mask to form a first via hole and a second via hole in the gate insulating layer.

Step S104: a gate electrode layer is deposited at a side of the gate insulating layer away from the active layer, and the gate electrode layer is patterned by using a fourth mask to form a gate electrode, a source electrode and a drain electrode, the source electrode is connected to a source region of the active layer through the first via hole, and the drain electrode is connected to a drain region of the active layer through the second via hole.

Step S105: a passivation layer is deposited at a side of the gate electrode layer away from the gate insulating layer, and a first color filter, a second color filter and a third color filter are formed on the passivation layer by using a fifth mask, a sixth mask and a seventh mask, respectively.

Step S106: an insulating layer is deposited at a side of the first color filter, the second color filter and the third color filter away from the passivation layer, and a third via hole is formed in the insulating layer by using an eighth mask.

Step S107: an anode layer is formed at a side of the insulating layer away from the first color filter, the second color filter and the third color filter, and the anode layer is patterned by using a ninth mask to form a plurality of anodes, each anode is connected to the drain electrode through the third via hole.

Step S108: a pixel-definition layer is formed at a side of the anode layer away from the insulating layer, and the pixel-definition layer is patterned by using a tenth mask to form a plurality of pixel openings.

It can be seen that the manufacturing method of the array substrate removes the masking processes of the source-drain metal layer and the interlayer insulating layer by forming the source electrode and the drain electrode from the gate electrode layer but adds the masking process of the gate insulating layer, and finally saves one masking process, thereby reducing the manufacturing cost. It is to be noted that in the above manufacturing process, the first color filter, the second color filter and the third color filter may not be provided on the passivation layer.

However, in the above manufacturing method, after the gate insulating layer is patterned and the first and second via holes are formed, one time of conductorization process is performed on the active layer; after the gate electrode layer is patterned and the gate electrode, the source electrode and the drain electrode are formed, another time of conductorization process is performed on the active layer; therefore, the active layer is conductorized for two times, which easily leads to a loss in the active layer, and in turn affects the conductive performance of the thin-film transistor.

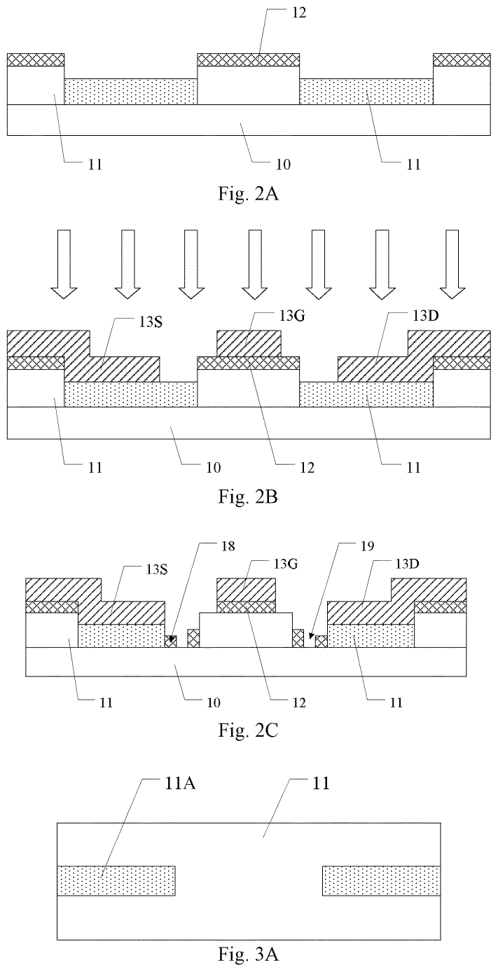

FIG. 2A-2C are schematic cross-sectional views of an active layer having a loss in a manufacturing method of an array substrate. As shown in FIG. 2A, the active layer 11 is located on the base substrate 10, and the gate insulating layer 12 is located at the side of the active layer 11 away from the base substrate 10; at this time, one time of conductorization process may be performed on the active layer 11 through the first via hole H1 and the second via hole H2 in the gate insulating layer 12. As shown in FIG. 2B, the gate electrode layer 13 is formed at the side of the gate insulating layer 12 away from the base substrate 10, and the gate electrode layer 13 is patterned to form a gate electrode 13G, a source electrode 13S and a drain electrode 13D. As shown in FIG. 2C, another time of conductorization process is performed on the active layer 11 by using the formed gate electrode 13G, the formed source electrode 13S and the formed drain electrode 13D as a mask, and an overlapping region subjected to the two times of conductorization processes will result in a partial loss 18 of the active layer or a complete loss 19 of the active layer.

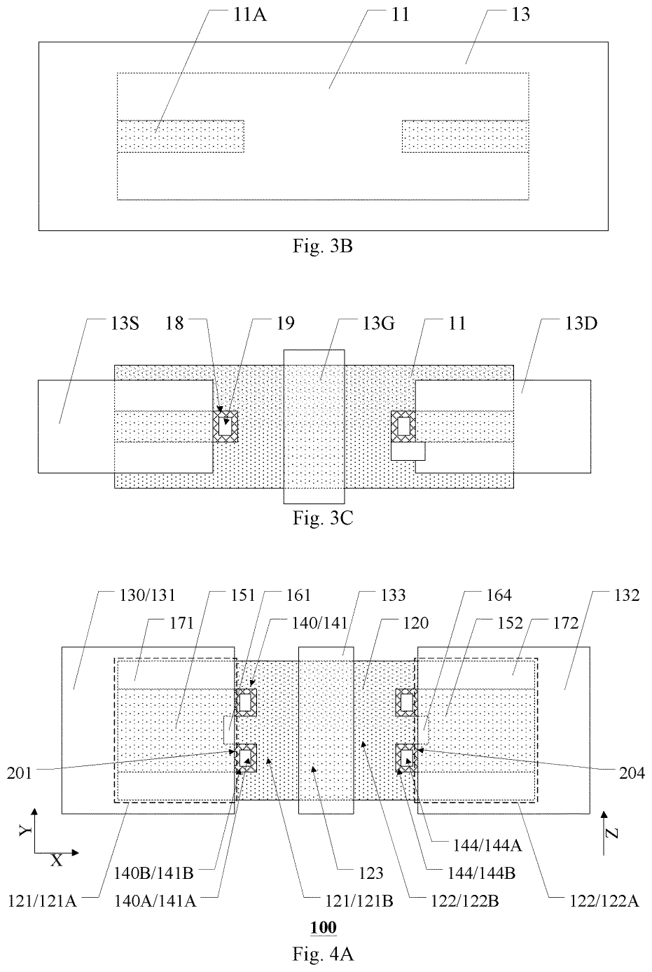

FIGS. 3A-3C are schematic plan views of an active layer having a loss in a manufacturing method of an array substrate. As shown in FIG. 3A, the active layer 11 is formed with a first conductorization region 11A after one time of conductorization process. As shown in FIG. 3B, the gate electrode layer 13 is formed at the side of the gate insulating layer away from the active layer 11. As shown in FIG. 3C, the gate electrode layer 13 is patterned to form a gate electrode 13G, a source electrode 13S and a drain electrode 13D, and another time of conductorization process is performed on the active layer 11 (i.e., the region outside the gate electrode, the source electrode and the drain electrode are conductorized) by using the formed gate electrode 13G, the formed source electrode 13S and the formed drain electrode 13D as a mask, and an overlapping region of the active layer subjected to the two times of conductorization processes will result in a partial loss 18 of the active layer or a complete loss 19 of the active layer.

As shown in FIG. 3C, a part of the active layer 11 close to the source electrode 13S or the drain electrode 13D is formed as a hollow structure 19 due to the two times of conductorization processes, and the source electrode 13S or the drain electrode 13D can only form a conductive channel through a narrow hollow edge 18 which has a width of only 0.5 μm−2 μm and a resistance R=ρL/S. Since a thickness of the hollow edge is only ⅓ to ¼ of that of the other parts of the active layer, the resistance of the hollow edge will also be three or four times as great as that of a traditional transistor, which considerably affects the performance of the transistor.

In this regard, an embodiment of the present disclosure discloses a thin-film transistor and a manufacturing method thereof, an array substrate and a display device. The thin-film transistor includes an active layer and an electrode layer. The active layer includes a channel region, and a first region and a second region located at two sides of the channel region, respectively, in a first direction. The electrode layer includes a gate electrode, a first electrode, and a second electrode. The first region includes a first lap region and a first transmission region, an orthographic projection of the first electrode on the active layer overlaps with the first lap region, the first transmission region includes at least one arc-shaped conductive structure, each arc-shaped conductive structure includes a hollow part and a thinning portion at least partially surrounding the hollow part, a thickness of the thinning portion is smaller than a thickness of the active layer in the channel region, and one arc-shaped conductive structure is connected to one edge of the first lap region, a size of an orthographic projection of the arc-shaped conductive structure on the edge is smaller than a length of the edge, and the thinning portion is located at a side of the hollow part close to the edge. In this way, a stable conductive channel can be formed between the first lap region and the first transmission region in the thin-film transistor by disposing at least one arc-shaped conductive structure in the first transmission region, thereby enhancing the conductivity of the thin-film transistor.

Hereinafter, a thin-film transistor and a manufacturing method thereof, an array substrate and a display device provided in the embodiments of the present disclosure are described in details in conjunction with the accompanying drawings.

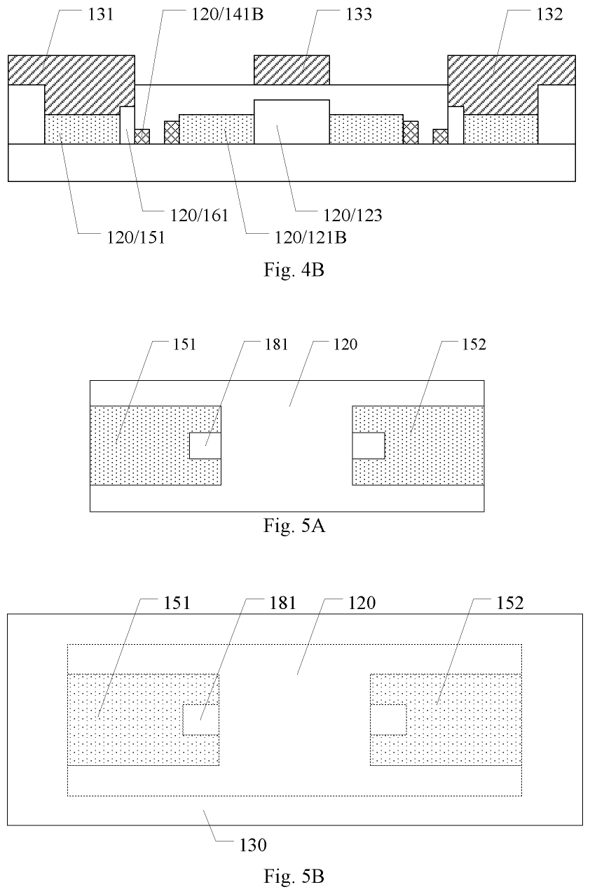

An embodiment of the present disclosure provides a thin-film transistor. FIG. 4A is a schematic plan view of a thin-film transistor provided in an embodiment of the present disclosure. As shown in FIG. 4A, the thin-film transistor 100 includes an active layer 120 and an electrode layer 130. The active layer 120 includes a channel region 123, and a first region 121 and a second region 122 located at two sides of the channel region 123 in a first direction X; that is, the first region 121, the channel region 123 and the second region 122 are arranged sequentially along the first direction X. The electrode layer 130 includes a gate electrode 133, a first electrode 131 and a second electrode 132. The first region 121 includes a first lap region 121A and a first transmission region 121B, an orthographic projection of the first electrode 131 on the active layer 120 overlaps with the first lap region 121A, the first transmission region 121B includes at least one arc-shaped conductive structure 140, each arc-shaped conductive structure 140 includes a hollow part 140A and a thinning portion 140B at least partially surrounding the hollow part 140A, a thickness of the thinning portion 140B is smaller than a thickness of the active layer 120 in the channel region 123. One of the arc-shaped conductive structure(s) 140 is connected to one edge of the first lap region 121A; that is, an edge of one arc-shaped conductive structure 140 is connected to the edge of the first lap region 121A, or the edge of the arc-shaped conductive structure 140 and the edge of the first lap region 121A are located on the same virtual line. A size of an orthographic projection of the arc-shaped conductive structure 140 on the edge is smaller than a length of the edge. The thinning portion 140B is located at a side of the hollow part 140A close to the edge. It is to be noted that the edge of the above arc-shaped conductive structure can be an area which extends 0.5-1.5 microns inwardly from an outer contour of the arc-shaped conductive structure.

In the thin-film transistor provided in the embodiment of the present disclosure, since one edge of the first lap region is provided with an arc-shaped conductive structure, a stable conductive channel can be formed between the first lap region and the first transmission region through the arc-shaped conductive structure, thereby enhancing the conductivity of the thin-film transistor. Moreover, since the size of the orthographic projection of the arc-shaped conductive structure on the edge is smaller than the length of the edge, the edge of the first lap region and the first transmission region can also form other conductive channels in addition to this arc-shaped conductive structure, such as other arc-shaped conductive structures, thereby increasing the number and quality of conductive channels between the first lap region and the first transmission region, and enhancing the conductivity of the thin-film transistor.

In some examples, as shown in FIG. 4A, a side of the hollow part 140A close to the edge and a side of the hollow part 140A away from the edge are both the thinning portion 140B. At this time, a plane shape of the thinning portion 140B is an annular shape.

However, it is to be noted that in some products, due to the process and other reasons, the thinning degree of the thinning portion at the side of the hollow part 140A close to the edge is greater than the thinning degree of the thinning portion at the side of the hollow part 140A away from the edge, that is, a thickness of the thinning portion at the side of the hollow part 140A close to the edge is smaller than a thickness of the thinning portion at the side of the hollow part 140A away from the edge. In such case, it's also possible that only the thinning portion at the side of the hollow part 140A close to the edge is regarded as the thinning portion 140B in the embodiment of the present disclosure, and a plane shape of the thinning portion 140B is an arc shape or a C shape. In summary, the plane shape of the thinning portion of the arc-shaped conductive structure provided by the embodiment of the present disclosure may be an arc shape or a C shape, or an annular shape.

It is to be noted that even if the plane shape of the thinning portion is an annular shape, when a current flows through the thinning portion at the side of the hollow part close to the edge, the current is not only transmitted in the annular-shaped thinning portion but can also be transmitted through other conductive parts of the first transmission region, so the annular-shaped conductive structure can be regarded as an arc-shaped conductive structure. Moreover, the thinning portions in the first arc-shaped conductive structure, the second arc-shaped conductive structure, the third arc-shaped conductive structure, the fourth arc-shaped conductive structure, the fifth arc-shaped conductive structure, and the sixth arc-shaped conductive structure to be described later can all refer to the description above.

In some examples, as shown in FIG. 4A, the first electrode 131 may be the source electrode, and the second electrode 132 is a drain electrode. Alternatively, the first electrode 131 is a drain electrode, and the second electrode 132 is a source electrode.

In some examples, as shown in FIG. 4A, at least one arc-shaped conductive structure 140 includes a first arc-shaped conductive structure 141, the first arc-shaped conductive structure 141 includes a first hollow part 141A and a first thinning portion 141B at least partly surrounding the first hollow part 141A, a thickness of the first thinning portion 141B is smaller than a thickness of the active layer 120 in the channel region 123. The first lap region 121A includes a first edge 201 extending along a second direction Y, the first edge 201 and the edge of the channel region 123 are disposed opposite to each other at an interval, the first arc-shaped conductive structure 141 is connected to the first edge 201, and a size of the first arc-shaped conductive structure 141 in the second direction Y is smaller than a length of the first edge 201, the second direction Y intersects with the first direction X.

In the thin-film transistor provided in this example, the first edge of the first lap region disposed in opposite to the channel region is provided with a first arc-shaped conductive structure, and a stable conductive channel can be formed between the first edge of the first lap region and the first transmission region through the first arc-shaped conductive structure, thereby enhancing the conductivity of the thin-film transistor. Moreover, since the size of the first arc-shaped conductive structure in the second direction is smaller than the length of the first edge, the first edge of the first lap region and the first transmission region can also form other conductive channels in addition to this arc-shaped conductive structure, such as other arc-shaped conductive structures, thereby increasing the number and quality of conductive channels between the first lap region and the first transmission region, and enhancing the conductivity of the thin-film transistor.

In some examples, as shown in FIG. 4A, at least one arc-shaped conductive structure 140 includes at least two first arc-shaped conductive structures 141, the first lap region 121A includes a first doped region 151 and a first functional region 161, the first functional region 161 is connected to the first edge 201 and is located between two first arc-shaped conductive structures 141 in the second direction Y. For example, the first functional region is an un-doped region or a semiconductor reserved region.

In the thin-film transistor provided in this example, the first lap region is provided with a first functional region connected to the first edge. In the first time of conductorization process for the active layer, the first doped region is conductorized or doped, the un-doped region including the first functional region is not conductorized or not doped; in the second time of conductorization process for the active layer, a part of the un-doped region including the first functional region undergoes one time of conductorization process and becomes a part of the first transmission region (a part located between two first arc-shaped conductive structures), and the other part of the un-doped region is not doped or conductorized and is formed as the first functional region. In such case, the part subjected to only one time of conductorization process will not generate a loss or a partial loss; as a result, the existence of the first functional region allows the above-mentioned two first arc-shaped conductive structures to be formed, so that a plurality of stable conductive channels can be formed between the first edge of the first lap region and the first transmission region, thereby enhancing the conductivity of the thin-film transistor.

It is to be noted that the above first arc-shaped conductive structures are formed after the active layer has been subjected to two times of conductorization processes, the first hollow part is a structure formed by a complete loss of the active layer, and the first thinning portion is a structure formed by a partial loss of the active layer. Accordingly, the present embodiment cleverly utilizes the partial loss phenomenon of the active layer after two times of conductorization processes to form two first arc-shaped conductive structures by providing an un-doped region including a first functional region, so that a plurality of stable conductive channels can be formed between the first edge of the first lap region and the first transmission region, thereby enhancing the conductivity of the thin-film transistors.

In some examples, as shown in FIG. 4A, a distance between two first arc-shaped conductive structures 141 is greater than a size of each first arc-shaped conductive structure 141 in the first direction, and is smaller than a size of the active layer 120 in the second direction.

In some examples, as shown in FIG. 4A, an area of the first functional region 161 is smaller than an area of the channel region 123.

In some examples, as shown in FIG. 4A, the area of the first functional region 161 is smaller than an area of the first thinning portion 141B.

In some examples, as shown in FIG. 4A, an area of the first lap region 121A is greater than the area of the channel region 123; or an area of the first doped region 151 is greater than the area of the channel region 123.

In some examples, as shown in FIG. 4A, a size of the first functional region 161 in the second direction Y is smaller than a size of the first doped region 151 in the second direction Y. In this way, it is possible to avoid an oversize of the first functional region in the thin-film transistor that may affect the conductivity of the first lap region.

In some examples, as shown in FIG. 4A, the area of the first functional region 161 is smaller than the area of the channel region 123, and the area of the first functional region 161 is smaller than an area of the first hollow part 141A. In this way, it is possible to avoid an oversize of the first functional region in the thin-film transistor that may affect the conductivity of the first lap region.

In some examples, as shown in FIG. 4A, the first lap region 121A further includes a first semiconductor region 171. The first semiconductor region 171 is located at two sides of the first doped region 151 in the second direction Y, and the area of the first functional region 161 is smaller than an area of the first semiconductor region 171.

In some examples, as shown in FIG. 4A, the second region 122 includes a second lap region 122A and a second transmission region 122B, an orthographic projection of the second electrode 132 on the active layer 120 overlaps with the second lap region 122A, the second transmission region 122B includes a fourth arc-shaped conductive structure 144, each fourth arc-shaped conductive structure 144 includes a fourth hollow part 144A and a fourth thinning portion 144B at least partially surrounding the fourth hollow part 144A, a thickness of the fourth thinning portion 144B is smaller than the thickness of the active layer 120 in the channel region 123, the second lap region 122A includes a fourth edge 204 extending along a third direction Z, the fourth edge 204 and the edge of the channel region 123 are disposed opposite to each other at an interval, the fourth arc-shaped conductive structure 144 is connected to the fourth edge 204, and a size of the fourth arc-shaped conductive structure 144 in the third direction Z is smaller than a length of the fourth edge 204, and the third direction intersects with the first direction.

In the thin-film transistor provided in this example, since the fourth edge of the second lap region is provided with a fourth arc-shaped conductive structure, a stable conductive channel can be formed between the second lap region and the second transmission region through the fourth arc-shaped conductive structure, thereby enhancing the conductivity of the thin-film transistor. Furthermore, since the size of the fourth arc-shaped conductive structure in the third direction is smaller than the length of the fourth edge, the fourth edge of the second lap region and the second transmission region can also form other conductive channels in addition to this arc-shaped conductive structure, such as other arc-shaped conductive structures, thereby increasing the number and quality of conductive channels between the second lap region and the second transmission region, and enhancing the conductivity of the thin-film transistor.

For example, the third direction and the first direction may be perpendicular to each other, and the third direction and the second direction may be parallel to each other. Of course, the embodiment of the present disclosure includes such case but is not limited thereto.

In some examples, as shown in FIG. 4A, the second transmission region 122B includes at least two fourth arc-shaped conductive structures 144, the second lap region 122A includes a second doped region 152 and a fourth functional region 164, the fourth functional region 164 is connected to the fourth edge 204 and is located between two fourth arc-shaped conductive structures 144 in the third direction Z.

In the thin-film transistor provided in this example, the second lap region is provided with a fourth functional region connected to the fourth edge. In the first time of conductorization process for the active layer, the second doped region is conductorized or doped, the un-doped region including the fourth functional region is not conductorized or doped; in the second time of conductorization process for the active layer, a part of the un-doped region including the fourth functional region undergoes one time of conductorization process and becomes part of the second transmission region (a part located between two fourth arc-shaped conductive structures), and the other part of the un-doped region is not doped or conductordized and is formed as the fourth functional region. In such case, the part subjected to only one time of conductorization process will not generate a loss or a partial loss; as a result, the existence of the fourth functional region allows the above-mentioned two fourth arc-shaped conductive structures to be formed, so that a plurality of stable conductive channels can be formed between the fourth edge of the second lap region and the second transmission region, thereby enhancing the conductivity of the thin-film transistor.

In some examples, as shown in FIG. 4A, the second lap region 122A further includes a second semiconductor region 172. The second semiconductor region 172 is located at two sides of the second doped region 152 in the second direction Y, and an area of the fourth functional region 164 is smaller than an area of the second semiconductor region 172.

FIG. 4B is a schematic cross-sectional view of a part of a thin-film transistor provided in an embodiment of the present disclosure. As shown in FIG. 4B, the active layer 120 has a first thickness a in the channel region 123, the active layer 120 has a second thickness b in the first doped region 151, the active layer 120 has a third thickness c in the first functional region 161, the first thinning portion 141B has a fourth thickness d, and the active layer 120 has a fifth thickness e in the first transmission region 121B. In such case, the first thickness a, the second thickness b, the third thickness c, the fourth thickness d, and the fifth thickness e satisfy the following formula:

a>c>b=e>d.

In this way, the thin-film transistor shown in FIG. 4B better shows the thicknesses of the active layer at different locations.

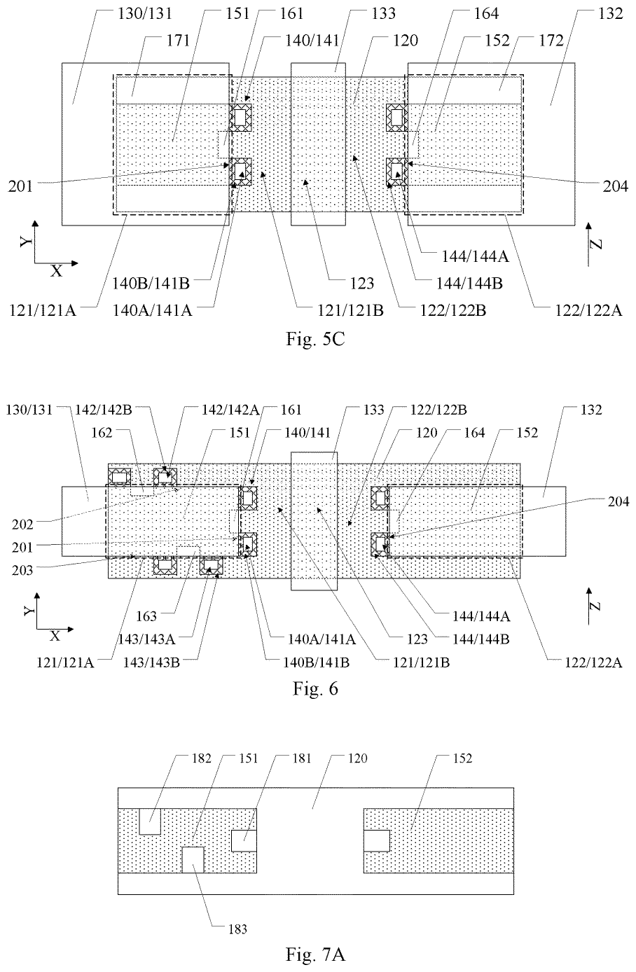

FIGS. 5A-5C are schematic diagrams illustrating steps of a manufacturing method of a thin-film transistor provided in an embodiment of the present disclosure.

As shown in FIG. 5A, a first doped region 151 and a first un-doped region 181 are formed on the active layer 120, and the first un-doped region 181 is partially surrounded by the first doped region 151. One edge of the first un-doped region 181 is aligned with one edge of the first doped region 151, that is, one edge of the first un-doped region 181 and one edge of the first doped region 151 are located on the same virtual line. It is to be noted that other regions, such as the channel region of the active layer 120, are also un-doped regions, and the first un-doped region 181 here is merely limited to the part surrounded by the first doped region 151.

For example, a gate insulating layer (not shown) is disposed on the active layer 120, the first doped region corresponds to an opening in the gate insulating layer, and the other regions covered by the gate insulating layer are not doped.

As shown in FIGS. 5B and 5C, a gate electrode layer 130 is formed on the gate insulating layer described above. The gate electrode layer 130 is then patterned to form a first electrode 131, a second electrode 132 and a gate electrode 133. The region where the first electrode 131 and the active layer 120 overlap is the first lap region 121A, the region where the second electrode 132 and the active layer 120 overlap is the second lap region 122A, and the region where the gate electrode 133 and the active layer 120 overlap is the channel region 123. The region between the first lap region 121A and the channel region 123 is the first transmission region 121B, and the region between the second lap region 122A and the channel region 123 is the second transmission region 122B. The first lap region 121A and the first transmission region 121B together constitute the first region 121. The second lap region 122A and the second transmission region 122B together constitute the second region 122.

As shown in FIG. 5C, the first electrode 131 and the first un-doped region 181 partially overlap. In the second time of conductorization process performed on the active layer 120 by using the electrode layer 130 as a mask, a part of the first un-doped region 181 not covered by the first electrode 131 is subjected to one time of conductorization process and becomes part of the first transmission region 121B (a part located between two first arc-shaped conductive structures 141), and a part of the first un-doped region 181 covered by the first electrode 131 is not doped or conductorized and is formed as the first functional region 161. In such case, the part of the first un-doped region 181 not covered by the first electrode 131 will not generate a loss or a partial loss because it undergoes only one time of conductorization process, and the part of the first doped region 151 not covered by the first electrode 131 will generate a loss or a partial loss after two times of conductorization processes to form two first arc-shaped conductive structures 141 spaced apart from each other, so that a plurality of stable conductive channels can be formed between the first lap region 121A and the first transmission region 121B, thereby enhancing the conductivity of the thin-film transistor.

It is to be noted that the above only describes the formation process of each structure in the first region with reference to FIG. 5A-FIG. 5C. It is understood that the second region can also have a structure similar or symmetrical to that of the first region, and its formation process can refer to the description above without repeating here.

An embodiment of the present disclosure also provides another thin-film transistor. FIG. 6 is a schematic plan view of a thin-film transistor provided in an embodiment of the present disclosure. As shown in FIG. 6, the thin-film transistor 100 includes an active layer 120 and an electrode layer 130. The active layer 120 includes a channel region 123, as well as a first region 121 and a second region 122 located at two sides of the channel region 123 in the first direction X. The electrode layer 130 includes a gate electrode 133, a first electrode 131 and a second electrode 132. The first region 121 includes a first lap region 121A and a first transmission region 121B, an orthographic projection of the first electrode 131 on the active layer 120 overlaps with the first lap region 121A, the first transmission region 121B includes at least one arc-shaped conductive structure 140. The at least one arc-shaped conductive structure 140 includes a first arc-shaped conductive structure 141, the first arc-shaped conductive structure 141 includes a first hollow part 141A and a first thinning portion 141B at least partially surrounding the first hollow part 141A, a thickness of the first thinning portion 141B is smaller than a thickness of the active layer 120 in the channel region 123. The first lap region 121A includes a first edge 201 extending along the second direction Y, the first edge 201 and the edge of the channel region 123 are disposed opposite to each other at an interval, the first arc-shaped conductive structure 141 is connected to the first edge 201, and a size of the first arc-shaped conductive structure 141 in the second direction Y is smaller than a length of the first edge 201, the second direction Y intersects with the first direction X. It is to be noted that the specific structure, number and location of the first arc-shaped conductive structure can refer to the related description of FIG. 4A, which will not be repeated here.

In the thin-film transistor provided in this embodiment, the first edge of the first lap region opposite to the channel region is provided with a first arc-shaped conductive structure, and a stable conductive channel can be formed between the first edge of the first lap region and the first transmission region through the first arc-shaped conductive structure, thereby enhancing the conductivity of the thin-film transistor. Moreover, since the size of the first arc-shaped conductive structure in the second direction is smaller than the length of the first edge, the first edge of the first lap region and the first transmission region can also form other conductive channels in addition to this arc-shaped conductive structure, such as other arc-shaped conductive structures, thereby increasing the number and quality of conductive channels between the first lap region and the first transmission region, and enhancing the conductivity of the thin-film transistor.

In some examples, as shown in FIG. 6, at least one arc-shaped conductive structure 140 further includes at least two second arc-shaped conductive structures 142, each second arc-shaped conductive structure 142 including a second hollow part 142A and a second thinning portion 142B at least partially surrounding the second hollow part 142A, a thickness of the second thinning portion 142B is smaller than the thickness of the active layer 120 in the channel region 123. The first lap region 121A further includes a second edge 202, the second edge 202 is connected to the first edge 201, the first lap region 121A further includes a second functional region 162, the second functional region 162 is connected to the second edge 202 and is located between two second arc-shaped conductive structures 142 in the first direction X, the second arc-shaped conductive structure 142 is connected to the second edge 202, and a size of the second arc-shaped conductive structure 142 in the first direction X is smaller than a length of the second edge 202.

In the display substrate provided by this example, in addition to the first edge, the second edge of the first lap region and the first transmission region can also form a stable conductive channel through two second arc-shaped conductive structures, thereby enhancing the conductivity of the thin-film transistor.

It is to be noted that although the display substrate shown in FIG. 6 includes both a first arc-shaped conductive structure and a second arc-shaped conductive structure, the embodiments of the present disclosure include such case but are not limited thereto. The at least one arc-shaped conductive structure in the display substrate may not include the first arc-shaped conductive structure, that is, the first edge of the first lap region is not provided with a first arc-shaped conductive structure, and the second edge of the first lap region is provided with the second arc-shaped conductive structure described above.

In some examples, as shown in FIG. 6, at least one arc-shaped conductive structure 140 further includes at least two third arc-shaped conductive structures 143, each third arc-shaped conductive structure 143 includes a third hollow part 143A and a third thinning portion 143B at least partially surrounding the third hollow part 143A, a thickness of the third thinning portion 143B is smaller than the thickness of the active layer 120 in the channel region 123. The first lap region 121A further includes a third edge 203, the third edge 203 is connected to the first edge 201, and the third edge 203 and the second edge 202 are disposed opposite to each other at an interval, the first lap region 121A further includes a third functional region 163, the third functional region 163 is connected to the third edge 203 and is located between two third arc-shaped conductive structures 143 in the first direction, the third arc-shaped conductive structure 143 is connected to the third edge 203, and a size of the third arc-shaped conductive structure 143 in the first direction is smaller than a length of the third edge 203.

In the display substrate provided by this example, in addition to the first edge and the second edge, the third edge of the first lap region and the first transmission region can also form a stable conductive channel through two third arc-shaped conductive structures, thereby enhancing the conductivity of the thin-film transistor. In such case, the three edges of the first lap region and the first transmission region can also form a stable conductive channel, respectively, which greatly increases the conductivity of the thin-film transistor and also increases the product yield.

It is to be noted that although the display substrate shown in FIG. 6 includes all of the first arc-shaped conductive structure, the second arc-shaped conductive structure and the third arc-shaped conductive structure, the embodiments of the present disclosure include such case but are not limited thereto. The at least one arc-shaped conductive structure in the display substrate may not include the first arc-shaped conductive structure or the second arc-shaped conductive structure described above; that is to say, the first edge of the first lap region is not provided with a first arc-shaped conductive structure and/or the second edge of the first lap region is not provided with a second arc-shaped conductive structure, and the third edge of the first lap region is provided with the third arc-shaped conductive structure described above.

In some examples, as shown in FIG. 6, the first functional region 161 and the second functional region 162 have a first distance D1 therebetween, the second functional region 162 and the third functional region 163 have a second distance D2 therebetween, the third functional region 163 and the first functional region 161 have a third distance D3 therebetween, and the first distance D1, the second distance D2 and the third distance D3 are all greater than a width of the first electrode 131 in the second direction Y. In this way, the thin-film transistor can ensure the conductive stability of the first doped region in the first lap region, and prevent the arrangement of the above-described functional regions from affecting the performance of the thin-film transistor.

In some examples, as shown in FIG. 6, an orthographic projection of the second functional region 162 on a reference line extending in the first direction X and an orthographic projection of the third functional region 163 on the reference line are disposed at an interval. That is to say, the second functional region 162 and the third functional region 163 are arranged in s staggered manner in the first direction, so that the area of the first lap region can be fully utilized, and the situation where the distance between the second functional region and the third functional region is too small due to the small size of the first lap region in the second direction Y can be avoided.

In some examples, as shown in FIG. 6, the distance between the second functional region 162 and the third functional region 163 is greater than a width of the channel region 123 in the first direction X. In this way, it further guarantees the conductivity of the first doped region in the thin-film transistor.

In some examples, as shown in FIG. 6, an area of the first lap region 121A is greater than an area of the channel region 123; or an area of the first doped region 151 is greater than the area of the channel region 123.

In some examples, as shown in FIG. 6, a size of the first functional region 161 in the second direction Y is smaller than a size of the first doped region 151 in the second direction Y. In this way, it is possible to avoid an oversize of the first functional region in the thin-film transistor that may affect the conductivity of the first lap region.

In some examples, as shown in FIG. 6, a size of the second functional region 162 in the first direction X is smaller than a size of the first doped region 151 in the first direction X. In this way, it is possible to avoid an oversize of the second functional region in the thin-film transistor that may affect the conductivity of the first lap region.

In some examples, as shown in FIG. 6, a size of the third functional region 163 in the first direction X is smaller than the size of the first doped region 151 in the first direction X. In this way, it is possible to avoid an oversize of the third functional region in the thin-film transistor that may affect the conductivity of the first lap region.

In some examples, as shown in FIG. 6, an area of the first functional region 161 is smaller than the area of the channel region 123, and the area of the first functional region 161 is smaller than an area of the first hollow part 141A. In this way, it is possible to avoid an oversize of the first functional region in the thin-film transistor that may affect the conductivity of the first lap region.

In some examples, as shown in FIG. 6, an area of the second functional region 162 is smaller than the area of the channel region 123, and the area of the second functional region 162 is smaller than an area of the second hollow part 142A. In this way, it is possible to avoid an oversize of the second functional region in the thin-film transistor that may affect the conductivity of the first lap region.

In some examples, as shown in FIG. 6, an area of the third functional region 163 is smaller than the area of the channel region 123, and the area of the third functional region 163 is smaller than an area of the third hollow part 143A. In this way, it is possible to avoid an oversize of the third functional region in the thin-film transistor that may affect the conductivity of the first lap region.

In some examples, as shown in FIG. 6, the first lap region 121A further includes a first semiconductor region 171. The first semiconductor region 171 is located at two sides of the first doped region 151 in the second direction Y, respectively, and an area of the first functional region 161 is smaller than an area of the first semiconductor region 171.

In some examples, as shown in FIG. 6, the second region 122 includes a second lap region 122A and a second transmission region 122B, an orthographic projection of the second electrode 132 on the active layer 120 overlaps with the second lap region 122A, the second transmission region 122B includes a fourth arc-shaped conductive structure 144, each fourth arc-shaped conductive structure 144 includes a fourth hollow part 144A and a fourth thinning portion 144B at least partially surrounding the fourth hollow part 144A. A thickness of the fourth thinning portion 144B is smaller than the thickness of the active layer 120 in the channel region 123. The second lap region 122A includes a fourth edge 204 extending along the third direction Z, the fourth edge 204 and the edge of the channel region 123 are disposed opposite to each other at an interval, the fourth arc-shaped conductive structure 144 is connected to the fourth edge 204, and a size of the fourth arc-shaped conductive structure 144 in the third direction Z is smaller than a length of the fourth edge 204, and the third direction intersects with the first direction.

In the thin-film transistor provided in this example, since the fourth edge of the second lap region is provided with a fourth arc-shaped conductive structure, a stable conductive channel can be formed between the second lap region and the second transmission region through the fourth arc-shaped conductive structure, thereby enhancing the conductivity of the thin-film transistor. Furthermore, since the size of the fourth arc-shaped conductive structure in the third direction is smaller than the length of the fourth edge, the fourth edge of the second lap region and the second transmission region can also form other conductive channels in addition to this arc-shaped conductive structure, such as other arc-shaped conductive structures, thereby increasing the number and quality of conductive channels between the second lap region and the second transmission region, thereby enhancing the conductivity of the thin-film transistor.

For example, the third direction and the first direction may be perpendicular to each other, and the third direction and the second direction may be parallel to each other. Of course, the embodiment of the present disclosure includes such case but is not limited thereto.

In some examples, as shown in FIG. 6, the second transmission region 122B includes at least two fourth arc-shaped conductive structures 144, the second lap region 122A includes a second doped region 152 and a fourth functional region 164, the fourth functional region 164 is connected to the fourth edge 204 and is located between two fourth arc-shaped conductive structures 144 in the third direction Z.

In the thin-film transistor provided in this example, the second lap region is provided with a fourth functional region connected to the fourth edge. In the first time of conductorization process for the active layer, the second doped region is conductorized or doped, the un-doped region including the fourth functional region is not conductorized or doped; in the second time of conductorization process for the active layer, a part of the un-doped region including the fourth functional region undergoes one time of conductorization process and becomes part of the second transmission region (a part located between two fourth arc-shaped conductive structures), and the other part of the un-doped region is not doped or conductordized and is formed as the fourth functional region. In such case, the part subjected to only one time of conductorization process will not generate a loss or a partial loss; as a result, the existence of the fourth functional region allows the above-mentioned two fourth arc-shaped conductive structures to be formed, so that a plurality of stable conductive channels can be formed between the fourth edge of the second lap region and the second transmission region, thereby enhancing the conductivity of the thin-film transistor.

It is to be noted that although the second region of the thin-film transistor shown in FIG. 6 is only provided with a fourth arc-shaped conductive structure, the embodiments of the present disclosure include such case but are not limited thereto, and the second region of the thin-film transistor may also adopt a structure similar or symmetrical to that of the first region.

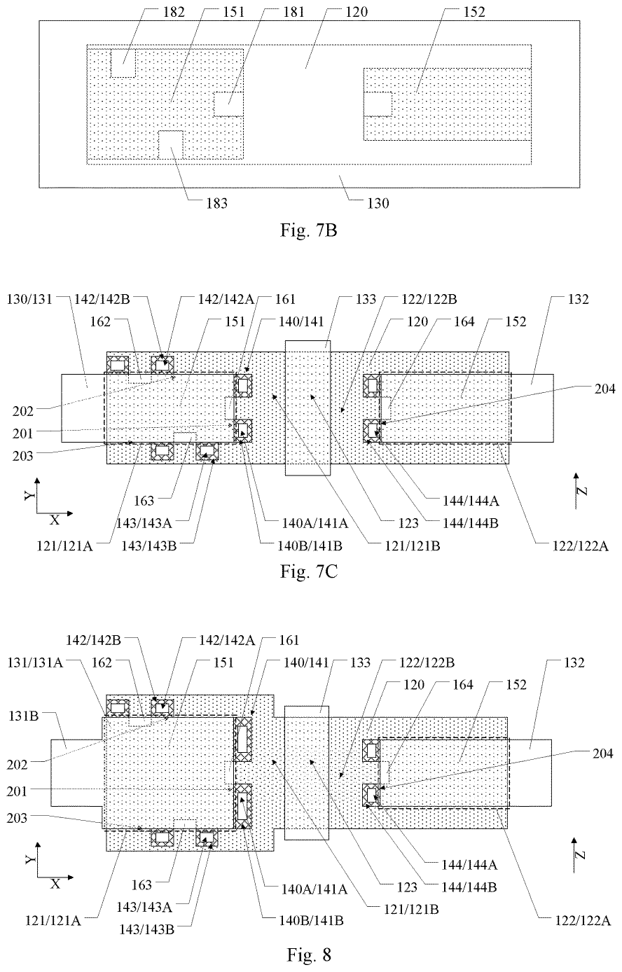

FIGS. 7A-7C are schematic diagrams illustrating steps of a manufacturing method of a thin-film transistor provided in an embodiment of the present disclosure.

As shown in FIG. 7A, a first doped region 151, a first un-doped region 181, a second un-doped region 182 and a third un-doped region 183 are formed on the active layer 120. For example, a doping process can be performed on the active layer 120 by using the gate insulating layer on the active layer 120 as a mask, a region exposed through an opening of the gate insulating layer is formed as the first doped region 151 described above, and a region not exposed through the opening of the gate insulating layer may be formed as the first un-doped region 181, the second un-doped region 182 and the third un-doped region 183 described above.

As shown in FIG. 7A, the first un-doped region 181 is partially surrounded by the first doped region 151. One edge of the first un-doped region 181 is aligned with one edge of the first doped region 151; that is to say, one edge of the first un-doped region 181 and one edge of the first doped region 151 are located on the same virtual line. The second un-doped region 182 is partially surrounded by the first doped region 151. One edge of the second un-doped region 182 is aligned with one edge of the first doped region 151; that is to say, one edge of the second un-doped region 182 and one edge of the first doped region 151 are located on the same virtual line. The third un-doped region 183 is partially surrounded by the first doped region 151. One edge of the third un-doped region 183 is aligned with one edge of the first doped region 151; that is to say, one edge of the third un-doped region 183 and one edge of the first doped region 151 are located on the same virtual line.

As shown in FIGS. 7B and 7C, a gate electrode layer 130 is formed on the gate insulating layer described above. The gate electrode layer 130 is then patterned to form a first electrode 131, a second electrode 132 and a gate electrode 133. The region where the first electrode 131 and the active layer 120 overlap is the first lap region 121A, the region where the second electrode 132 and the active layer 120 overlap is the second lap region 122A, and the region where the gate electrode 133 and the active layer 120 overlap is the channel region 123. The region between the first lap region 121A and the channel region 123 is the first transmission region 121B, and the region between the second lap region 122A and the channel region 123 is the second transmission region 122B. The first lap region 121A and the first transmission region 121B together constitute the first region 121. The second lap region 122A and the second transmission region 122B together constitute the second region 122.

As shown in FIG. 7C, the first electrode 131 and the first un-doped region 181 partially overlap. In the second time of conductorization process performed on the active layer 120 by using the electrode layer 130 as a mask, a part of the first un-doped region 181 not covered by the first electrode 131 is subjected to one time of conductorization process and becomes part of the first transmission region 121B (a part located between two first arc-shaped conductive structures 141), a part of the first un-doped region 181 covered by the first electrode 131 is not doped or conductorized and is formed as the first functional region 161. In such case, the part of the first un-doped region 181 not covered by the first electrode 131 will not generate a loss or a partial loss because it undergoes only one time of conductorization process, and the part of the first doped region 151 not covered by the first electrode 131 will generate a loss or a partial loss after two times of conductorization processes to form two first arc-shaped conductive structures 141 spaced apart from each other, so that a plurality of stable conductive channels can be formed between the first lap region 121A and the first transmission region 121B, thereby enhancing the conductivity of the thin-film transistor.

As shown in FIG. 7C, the first electrode 131 and the second un-doped region 182 partially overlap. In the second time of conductorization process performed on the active layer 120 by using the electrode layer 130 as a mask, a part of the second un-doped region 182 not covered by the first electrode 131 is subjected to one time of conductorization process and becomes part of the first transmission region 121B (a part located between two second arc-shaped conductive structures 142), and a part of the second un-doped region 182 covered by the first electrode 131 is not doped or conductorized and is formed as a second functional region 162. In such case, the part of the second un-doped region 182 not covered by the first electrode 131 will not generate a loss or a partial loss because it undergoes only one time of conductorization process, and the part of the first doped region 151 not covered by the first electrode 131 will generate a loss or a partial loss after two times of conductorization processes to form two second arc-shaped conductive structures 142 spaced apart from each other, so that a plurality of stable conductive channels can be formed between the first lap region 121A and the first transmission region 121B, thereby enhancing the conductivity of the thin-film transistor.

As shown in FIG. 7C, the first electrode 131 and the third un-doped region 183 partially overlap. In the second time of conductorization process performed on the active layer 120 by using the electrode layer 130 as a mask, a part of the third un-doped region 183 not covered by the first electrode 131 is subjected to one time of conductorization process and becomes part of the first transmission region 121B (a part located between two third arc-shaped conductive structures 143), and a part of the third un-doped region 183 covered by the first electrode 131 is not doped or conductorized and is formed as a third functional region 163. In such case, the part of the third un-doped region 183 not covered by the first electrode 131 will not generate a loss or a partial loss because it undergoes only one time of conductorization process, and the part of the first doped region 151 not covered by the first electrode 131 will generate a loss or a partial loss after two times of conductorization processes to form two third arc-shaped conductive structures 143 spaced apart from each other, so that a plurality of stable conductive channels can be formed between the first lap region 121A and the first transmission region 121B, thereby enhancing the conductivity of the thin-film transistor.

It is to be noted that the above only describes the formation process of each structure in the first region with reference to FIG. 7A-FIG. 7C. It is understood that the second region can also have a structure similar or symmetrical to that of the first region, and its formation process can refer to the above description and will not be repeated here.

An embodiment of the present disclosure also provides another thin-film transistor. FIG. 8 is a schematic plan view of another thin-film transistor provided in an embodiment of the present disclosure. As shown in FIG. 8, the thin-film transistor 100 includes an active layer 120 and an electrode layer 130. The active layer 120 includes a channel region 123, as well as a first region 121 and a second region 122 located at two sides of the channel region 123 in a first direction X. The electrode layer 130 includes a gate electrode 133, a first electrode 131 and a second electrode 132. The first region 121 includes a first lap region 121A and a first transmission region 121B, an orthographic projection of the first electrode 131 on the active layer 120 overlaps with the first lap region 121A, the first transmission region 121B includes at least one arc-shaped conductive structure 140. The at least one arc-shaped conductive structure 140 includes a first arc-shaped conductive structure 141, a second arc-shaped conductive structure 142 and a third arc-shaped conductive structure 143. The first arc-shaped conductive structure 141 includes a first hollow part 141A and a first thinning portion 141B at least partially surrounding the first hollow part 141A, a thickness of the first thinning portion 141B is smaller than a thickness of the active layer 120 in the channel region 123. The second arc-shaped conductive structure 142 includes a second hollow part 142A and a second annular-shaped thinning film 142B at least partially surrounding the second hollow part 142A, a thickness of the second thinning portion 142B is smaller than the thickness of the active layer 120 in the channel region 123. The third arc-shaped conductive structure 143 includes a third hollow part 143A and a third annular-shaped thinning film 143B at least partially surrounding the third hollow part 143A, a thickness of the third thinning portion 143B is smaller than the thickness of the active layer 120 in the channel region 123.

The first lap region 121A includes a first edge 201, a second edge 202 and a third edge 203; the first arc-shaped conductive structure 141 is connected to the first edge 201, the second arc-shaped conductive structure 142 is connected to the second edge 202, and the third arc-shaped conductive structure 143 is connected to the third edge 203. It is to be noted that the specific structure, number and location of the first arc-shaped conductive structure, the second arc-shaped conductive structure and the third arc-shaped conductive structure can refer to the related description of FIG. 6, which will not be repeated here.

In the thin-film transistor provided in this embodiment, the first edge of the first lap region is provided with the first arc-shaped conductive structure, the second edge of the first lap region is provided with the second arc-shaped conductive structure, and the third edge of the first lap region is provided with the third arc-shaped conductive structure, so that the three edges of the first lap region and the first transmission region can form a plurality of stable conductive channels through the first arc-shaped conductive structure, the second arc-shaped conductive structure and the third arc-shaped conductive structure, respectively, thereby enhancing the conductivity of the thin-film transistor.

In some examples, as shown in FIG. 8, the first lap region 121A includes a first functional region 161, a second functional region 162 and a third functional region 163; the first functional region 161 is connected to the first edge 201, the second functional region 162 is connected to the second edge 202, and the third functional region 163 is connected to the third edge 203.

In some examples, as shown in FIG. 8, the first electrode 131 includes a protrusion portion 131A and an extension portion 131B, the extension portion 131B is located at a side of the protrusion portion 131A away from the channel region 123, a size of the protrusion portion 131A in a second direction Y is greater than a size of the extension portion 131B in the second direction Y, and a size of the protrusion portion 131A in the second direction Y is greater than the sum of a size of the second functional region 162 in the second direction Y and a size of the third functional region 163 in the second direction Y. In this way, the formation of the above-described protrusion portion in the thin-film transistor can enable a distance between the second functional region and the third functional region to be large enough to ensure the conductivity of the first lap region.

In some examples, the first functional region 161, the second functional region 162 and the third functional region 163 are all un-doped regions or semiconductor reserved regions. That is to say, the first, second, and third functional regions are all semiconductors and cannot conduct electricity.

In some examples, as shown in FIG. 8, a distance between the second functional region 162 and the third functional region 163 is greater than a size of the channel region 123 in the first direction X. In this way, the formation of the above-described protrusion portion in the thin-film transistor can enable the distance between the second functional region and the third functional region to be large enough to ensure the conductivity of the first lap region.

In some examples, as shown in FIG. 8, an area of the first lap region 121A is greater than an area of the channel region 123; or an area of the first doped region 151 is greater than the area of the channel region 123.

In some examples, as shown in FIG. 8, a size of the first functional region 161 in the second direction Y is smaller than a size of the first doped region 151 in the second direction Y. In this way, it is possible to avoid an oversize of the first functional region in the thin-film transistor that may affect the conductivity of the first lap region.

In some examples, as shown in FIG. 8, a size of the second functional region 162 in the first direction X is smaller than a size of the first doped region 151 in the first direction X. In this way, it is possible to avoid an oversize of the second functional region in the thin-film transistor that may affect the conductivity of the first lap region.

In some examples, as shown in FIG. 8, a size of the third functional region 163 in the first direction X is smaller than the size of the first doped region 151 in the first direction X. In this way, it is possible to avoid an oversize of the third functional region in the thin-film transistor that may affect the conductivity of the first lap region.

In some examples, as shown in FIG. 8, an area of the first functional region 161 is smaller than an area of the channel region 123, and the area of the first functional region 161 is smaller than an area of the first hollow part 141A. In this way, it is possible to avoid an oversize of the first functional region in the thin-film transistor that may affect the conductivity of the first lap region.

In some examples, as shown in FIG. 8, an area of the second functional region 162 is smaller than the area of the channel region 123, and the area of the second functional region 162 is smaller than an area of the second hollow part 142A. In this way, it is possible to avoid an oversize of the second functional region in the thin-film transistor that may affect the conductivity of the first lap region.

In some examples, as shown in FIG. 8, an area of the third functional region 163 is smaller than the area of the channel region 123, and the area of the third functional region 163 is smaller than an area of the third hollow part 143A. In this way, it is possible to avoid an oversize of the third functional region in the thin-film transistor that may affect the conductivity of the first lap region.

In some examples, as shown in FIG. 8, the first lap region 121A further includes a first semiconductor region 171. The first semiconductor region 171 is located at two sides of the first doped region 151 in the second direction Y, and the area of the first functional region 161 is smaller than an area of the first semiconductor region 171.

In some examples, as shown in FIG. 8, the second region 122 includes a second lap region 122A and a second transmission region 122B, an orthographic projection of the second electrode 132 on the active layer 120 overlaps with the second lap region 122A, the second transmission region 122B includes a fourth arc-shaped conductive structure 144, each fourth arc-shaped conductive structure 144 includes a fourth hollow part 144A and a fourth thinning portion 144B at least partially surrounding the fourth hollow part 144A. A thickness of the fourth thinning portion 144B is smaller than a thickness of the active layer 120 in the channel region 123, the second lap region 122A includes a fourth edge 204 extending along a third direction to Z, the fourth edge 204 and the edge of the channel region 123 are disposed opposite to each other at an interval, the fourth arc-shaped conductive structure 144 is connected to the fourth edge 204, and a size of the fourth arc-shaped conductive structure 144 in the third direction Z is smaller than a length of the fourth edge 204, and the third direction intersects with the first direction.

In the thin-film transistor provided in this example, since the fourth edge of the second lap region is provided with a fourth arc-shaped conductive structure, a stable conductive channel can be formed between the second lap region and the second transmission region through the fourth arc-shaped conductive structure, thereby enhancing the conductivity of the thin-film transistor. Furthermore, since the size of the fourth arc-shaped conductive structure in the third direction is smaller than the length of the fourth edge, the fourth edge of the second lap region and the second transmission region can also form other conductive channels in addition to this arc-shaped conductive structure, such as other arc-shaped conductive structures, thereby increasing the number and quality of conductive channels between the second lap region and the second transmission region, and enhancing the conductivity of the thin-film transistor.

For example, the third direction and the first direction may be perpendicular to each other, and the third direction and the second direction may be parallel to each other. Of course, the embodiment of the present disclosure includes such case but is not limited thereto.

In some examples, as shown in FIG. 8, the second transmission region 122B includes at least two fourth arc-shaped conductive structures 144, the second lap region 122A includes a second doped region 152 and a fourth functional region 164, the fourth functional region 164 is connected to the fourth edge 204 and is located between two fourth arc-shaped conductive structures 144 in the third direction Z.

In the thin-film transistor provided in this example, the second lap region is provided with a fourth functional region connected to the fourth edge. In the first time of conductorization process for the active layer, the second doped region is conductorized or doped, and the un-doped region including the fourth functional region is not conductorized or doped. In the second time of conductorization process for the active layer, a part of the un-doped region including the fourth functional region undergoes one time of conductorization process and becomes part of the second transmission region (a part located between two fourth arc-shaped conductive structures), and the other part of the un-doped region is not doped or conductorized and is formed as a fourth functional region. In such case, the part subjected to only one time of conductorization process will not generate a loss or a partial loss; as a result, the existence of the fourth functional region allows the above-mentioned two fourth arc-shaped conductive structures to be formed, so that a plurality of stable conductive channels can be formed between the fourth edge of the second lap region and the second transmission region, thereby enhancing the conductivity of the thin-film transistor.

It is to be noted that although the second region of the thin-film transistor shown in FIG. 8 is only provided with a fourth arc-shaped conductive structure, the embodiments of the present disclosure include such case but are not limited thereto, and the second region of the thin-film transistor may also adopt a structure similar or symmetrical to that of the first region.

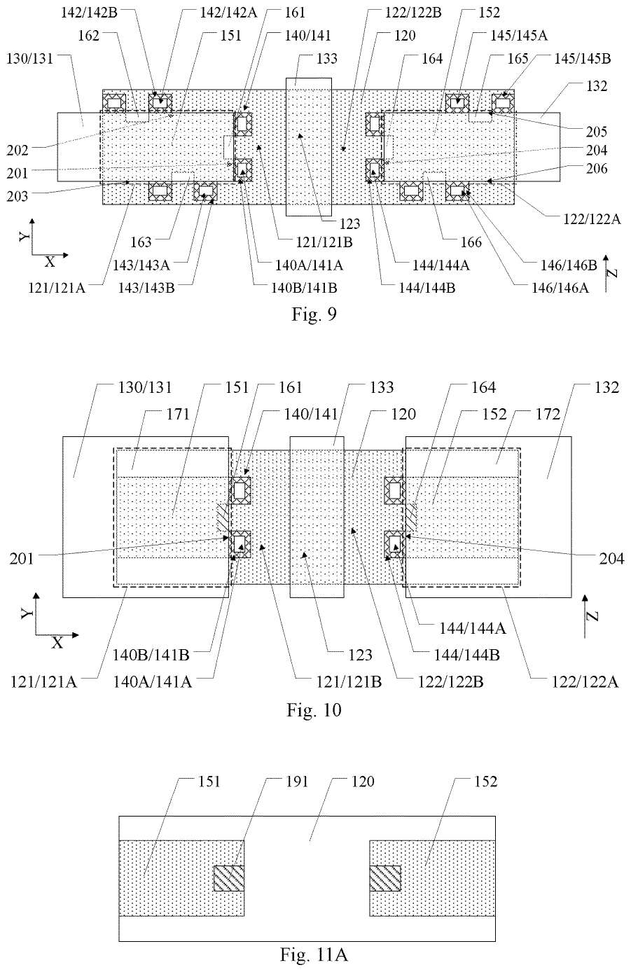

An embodiment of the present disclosure also provides another thin-film transistor. FIG. 9 is a schematic plan view of a thin-film transistor provided in an embodiment of the present disclosure. As shown in FIG. 9, the thin-film transistor 100 includes an active layer 120 and an electrode layer 130. The active layer 120 includes a channel region 123, as well as a first region 121 and a second region 122 located at two sides of the channel region 123 in a first direction X. The electrode layer 130 includes a gate electrode 133, a first electrode 131 and a second electrode 132. The first region 121 includes a first lap region 121A and a first transmission region 121B, an orthographic projection of the first electrode 131 on the active layer 120 overlaps with the first lap region 121A, the first transmission region 121B includes at least one arc-shaped conductive structure 140. The at least one arc-shaped conductive structure 140 includes a first arc-shaped conductive structure 141, a second arc-shaped conductive structure 142 and a third arc-shaped conductive structure 143. The first arc-shaped conductive structure 141 includes a first hollow part 141A and a first thinning portion 141B at least partially surrounding the first hollow part 141A, a thickness of the first thinning portion 141B is smaller than a thickness of the active layer 120 in the channel region 123. The second arc-shaped conductive structure 142 includes a second hollow part 142A and a second annular-shaped thinning film 142B at least partially surrounding the second hollow part 142A, a thickness of the second thinning portion 142B is smaller than the thickness of the active layer 120 in the channel region 123. The third arc-shaped conductive structure 143 includes a third hollow part 143A and a third annular-shaped thinning film 143B at least partially surrounding the third hollow part 143A, a thickness of the third thinning portion 143B is smaller than the thickness of the active layer 120 in the channel region 123.

The first lap region 121A includes a first edge 201, a second edge 202 and a third edge 203; the first arc-shaped conductive structure 141 is connected to the first edge 201, the second arc-shaped conductive structure 142 is connected to the second edge 202, and the third arc-shaped conductive structure 143 is connected to the third edge 203. It is to be noted that the specific structure, number and location of the first arc-shaped conductive structure, the second arc-shaped conductive structure and the third arc-shaped conductive structure can refer to the related description of FIG. 6, which will not be repeated here.

In the thin-film transistor provided in this embodiment, the first edge of the first lap region is provided with a first arc-shaped conductive structure, the second edge of the first lap region is provided with a second arc-shaped conductive structure, and the third edge of the first lap region is provided with a third arc-shaped conductive structure, so that the three edges of the first lap region and the first transmission region can form a plurality of stable conductive channels through the first arc-shaped conductive structure, the second arc-shaped conductive structure and the third arc-shaped conductive structure, respectively, thereby enhancing the conductivity of the thin-film transistor.

In some examples, as shown in FIG. 9, the second region 122 includes a second lap region 122A and a second transmission region 122B, an orthographic projection of the second electrode 132 on the active layer 120 overlaps with the second lap region 122A, the second transmission region 122B includes a fourth arc-shaped conductive structure 144, each fourth arc-shaped conductive structure 144 includes a fourth hollow part 144A and a fourth thinning portion 144B at least partially surrounding the fourth hollow part 144A. A thickness of the fourth thinning portion 144B is smaller than a thickness of the active layer 120 in the channel region 123, the second lap region 122A includes a fourth edge 204 extending along a third direction Z, the fourth edge 204 and the edge of the channel region 123 are disposed opposite to each other at an interval, the fourth arc-shaped conductive structure 144 is connected to the fourth edge 204, and a size of the fourth arc-shaped conductive structure 144 in the third direction Z is smaller than a length of the fourth edge 204, and the third direction intersects with the first direction.

In the thin-film transistor provided in this example, since the fourth edge of the second lap region is provided with a fourth arc-shaped conductive structure, a stable conductive channel can be formed between the second lap region and the second transmission region through the fourth arc-shaped conductive structure, thereby enhancing the conductivity of the thin-film transistor. Furthermore, since the size of the fourth arc-shaped conductive structure in the third direction is smaller than the length of the fourth edge, the fourth edge of the second lap region and the second transmission region can also form other conductive channels in addition to this arc-shaped conductive structure, such as other arc-shaped conductive structures, thereby increasing the number and quality of conductive channels between the second lap region and the second transmission region, and enhancing the conductivity of the thin-film transistor.

For example, the third direction and the first direction may be perpendicular to each other, and the third direction and the second direction may be parallel to each other. Of course, the embodiment of the present disclosure includes such case but is not limited thereto.

In some examples, as shown in FIG. 9, in addition to the fourth arc-shaped conductive structure 144 described above, the second transmission region 122B further includes at least two fifth arc-shaped conductive structures 145, each fifth arc-shaped conductive structure 145 includes a fifth hollow part 145A and a fifth thinning portion 145B at least partially surrounding the fifth hollow part 145A, a thickness of the fifth thinning portion 145B is smaller than a thickness of the active layer 120 in the channel region 123. The second lap region 122A further includes a fifth edge 205, the fifth edge 205 is connected to the fourth edge 204, the second lap region 122A further includes a fifth functional region 165, the fifth functional region 165 is connected to the fifth edge 205 and is located between two fifth arc-shaped conductive structures 145, the fifth arc-shaped conductive structure 145 is connected to the fifth edge 205, and a size of the fifth arc-shaped conductive structure 145 in the first direction is smaller than a length of the fifth edge 205.

In the display substrate provided by this example, in addition to the fourth edge, the fifth edge of the second lap region and the second transmission region can also form a stable conductive channel through at least two fifth arc-shaped conductive structures, thereby enhancing the conductivity of the thin-film transistor.

It is to be noted that although the display substrate shown in FIG. 9 includes both a fourth arc-shaped conductive structure and a fifth arc-shaped conductive structure, the embodiments of the present disclosure include such case but are not limited thereto; the fourth edge of the second lap region may not be provided with a fourth arc-shaped conductive structure, and the fifth edge of the second lap region is provided with the fifth arc-shaped conductive structure described above.

In some examples, as shown in FIG. 9, the second transmission region 122B further includes at least two sixth arc-shaped conductive structures 146, each sixth arc-shaped conductive structure 146 includes a sixth hollow part 146A and a sixth thinning portion 146B at least partially surrounding the sixth hollow part 146A, a thickness of the sixth thinning portion 146B is smaller than a thickness of the active layer 120 in the channel region 123. The second lap region 122A further includes a sixth edge 206, the sixth edge 206 is connected to the fourth edge 204, and the sixth edge 206 and the fifth edge 205 are disposed opposite to each other at an interval, the second lap region 122A further includes a sixth functional region 166, the sixth functional region 166 is connected to the sixth edge 206 and is located between two sixth arc-shaped conductive structures 146, the sixth arc-shaped conductive structure 146 is connected to the sixth edge 206, and a size of the sixth arc-shaped conductive structure 146 in the first direction X is smaller than a length of the sixth edge 206.

In the display substrate provided by this example, in addition to the fourth and fifth edges, the sixth edge of the second lap region and the second transmission region can also form a stable conductive channel through at least two sixth arc-shaped conductive structures, thereby enhancing the conductivity of the thin-film transistor.

It is to be noted that although the display substrate shown in FIG. 9 includes all of a fourth arc-shaped conductive structure, a fifth arc-shaped conductive structure and a sixth arc-shaped conductive structure, the embodiments of the present disclosure include such case but are not limited thereto; the fourth edge of the second lap region may not be provided with a fourth arc-shaped conductive structure and/or the fifth edge of the second lap region may not be provided with the fifth arc-shaped conductive structure described above, and the sixth edge of the second lap region is provided with the sixth arc-shaped conductive structure described above.

In some examples, as shown in FIG. 9, the fourth functional region 164 and the fifth functional region 165 have a fourth distance D4 therebetween, the fifth functional region 165 and the sixth functional region 166 have a fifth distance D5 therebetween, and the sixth functional region 166 and the fourth functional region 164 have a sixth distance D4 therebetween. The fourth distance D4, the fifth distance D5 and the sixth distance D6 are all greater than a width of the second electrode 132 in the second direction. In this way, the thin-film transistor can ensure the conductive stability of the second doped region in the second lap region, and prevent the arrangement of the above-described functional regions from affecting the performance of the thin-film transistor.

In some examples, as shown in FIG. 9, an orthographic projection of the fifth functional region 165 on a reference line extending in the first direction and an orthographic projection of the sixth functional region 166 on the reference line are spaced apart from each other. That is to say, the fifth functional region 165 and the sixth functional region 166 are arranged in a staggered manner in the first direction, so that the area of the second lap region can be fully utilized, and a small distance between the fifth functional region and the sixth functional region due to a small size of the second lap region in the second direction Y can be avoided.

In some examples, as shown in FIG. 9, a distance between the orthographic projection of the fifth functional region 165 on the reference line and the orthographic projection of the sixth functional region 166 on the reference line is greater than a distance between two adjacent fifth arc-shaped conductive structures 145 in the first direction.

In some examples, as shown in FIG. 9, the distance between the fifth functional region 165 and the sixth functional region 166 is greater than the width of the channel region 120 in the first direction X. In this way, the poor conductivity of the second lap region of the thin-film transistor due to too small distance between the fifth functional region and the sixth functional region can be avoided.

In some examples, as shown in FIG. 9, the fourth functional region 164, the fifth functional region 165 and the sixth functional region 166 are all un-doped regions or semiconductor reserved regions. That is to say, the first, second, and third functional regions are all semiconductors and cannot conduct electricity.

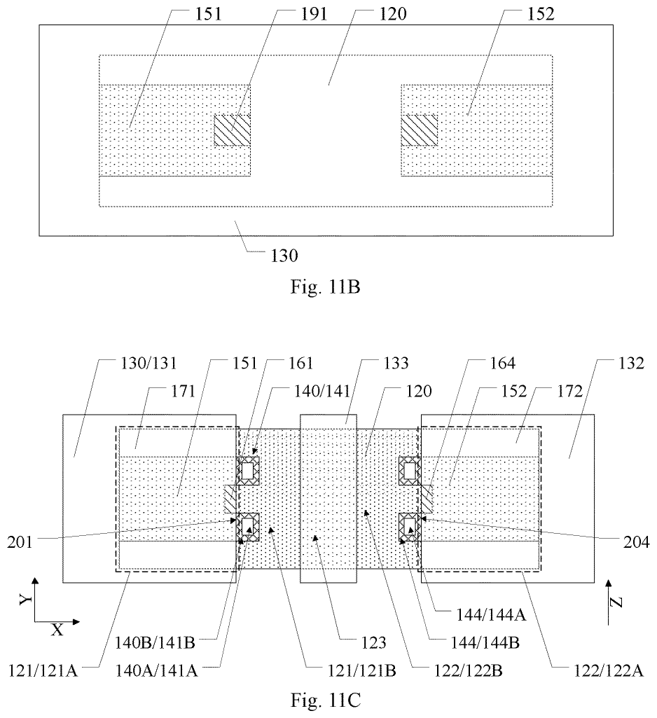

An embodiment of the present disclosure also provides another thin-film transistor. FIG. 10 is a schematic plan view of another thin-film transistor provided in an embodiment of the present disclosure. As shown in FIG. 10, the thin-film transistor 100 includes an active layer 120 and an electrode layer 130. The active layer 120 includes a channel region 123, as well as a first region 121 and a second region 122 located at two sides of the channel region 123 in a first direction X. That is to say, the first region 121, the channel region 123 and the second region 122 are arranged sequentially along the first direction X. The electrode layer 130 includes a gate electrode 133, a first electrode 131 and a second electrode 132. The first region 121 includes a first lap region 121A and a first transmission region 121B, an orthographic projection of the first electrode 131 on the active layer 120 overlaps with the first lap region 121A, the first transmission region 121B includes at least one arc-shaped conductive structure 140, the at least one arc-shaped conductive structure 140 includes at least two first arc-shaped conductive structures 141, the first lap region 121A includes a first doped region 151 and a first functional region 161, the first functional region 161 is connected to a first edge 201 and is located between two first arc-shaped conductive structures 141 in a second direction Y. Unlike other embodiments described above, the first functional region 161 described above is a semi-doped region.

In the thin-film transistor provided by this example, in the first time of conductorization process for the active layer, the first doped region is conductorized or doped, a region including the first functional region is semi-doped (e.g., forming a semi-doped region by partially blocking); in the second time of conductorization process for the active layer, a part of the semi-doped region including the first functional region undergoes one time of conductorization process and becomes part of the first transmission region (a part located between two first arc-shaped conductive structures), and the other part of the semi-doped region remains semi-doped and is formed as the first functional region. In such case, the part subjected to only one time of complete conductorization process will not generate a loss or a partial loss; as a result, the existence of the first functional region allows the above-described two first arc-shaped conductive structures to be formed, so that a plurality of stable conductive channels can be formed between the first edge of the first lap region and the first transmission region, thereby enhancing the conductivity of the thin-film transistor. Moreover, since the first functional region itself is a semi-doped region with certain conductive capability, the first functional region can also increase the number of conductive channels that can be formed between the first edge of the first lap region and the first transmission region, thereby further enhancing the conductivity of the thin-film transistor.

In some examples, as shown in FIG. 10, the second transmission region 122B may also include the fourth arc-shaped conductive structure 144 and the fourth functional region 164 described above. Similarly, the fourth functional region 164 may also be a semi-doped region, thereby further enhancing the conductivity of the thin-film transistor.

It is to be noted that the first transmission region in the thin-film transistor shown in FIG. 10 includes only the first arc-shaped conductive structure, and the second transmission region includes only the fourth arc-shaped conductive structure. However, the embodiments of the present disclosure include such case but are not limited thereto, the thin-film transistor shown in FIG. 10 may also include a second arc-shaped conductive structure, a third arc-shaped conductive structure, a fifth arc-shaped conductive structure, and a sixth arc-shaped conductive structure as shown in FIG. 9. In such case, at least one of the second functional region, the third functional region, the fifth functional region and the sixth functional region can be a semi-doped region, which can further improve the conductivity of the thin-film transistor.

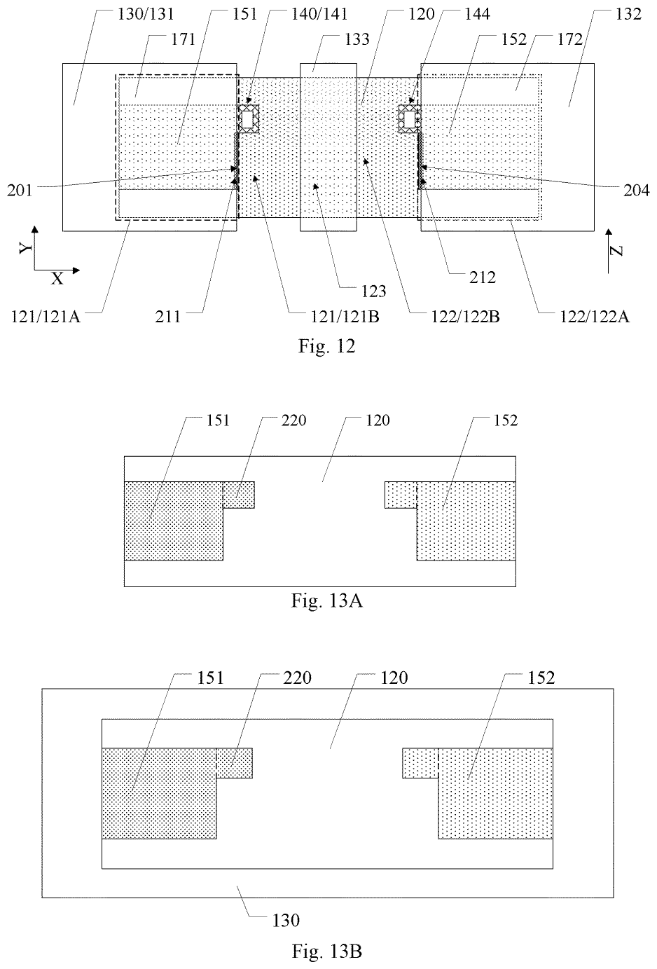

FIGS. 11A-11C are schematic diagrams illustrating steps of a manufacturing method of a thin-film transistor provided in an embodiment of the present disclosure.

As shown in FIG. 11A, a first doped region 151 and a first semi-doped region 191 are formed on the active layer 120, and the first semi-doped region 191 is partially surrounded by the first doped region 151. For example, a doping process can be performed on the active layer 120 by using the gate insulating layer on the active layer 120 as a mask, a region exposed through an opening of the gate insulating layer is formed as the first doped region 151 described above, and a region corresponding to a semi-etched portion of the gate insulating layer (formed by using a halftone mask) may be formed as the first semi-doped region 191 described above.

As shown in FIG. 11A, one edge of the first semi-doped region 191 is aligned with one edge of the first doped region 151; that is to say, one edge of the first semi-doped region 191 and one edge of the first doped region 151 are located on the same virtual line.

As shown in FIGS. 11B and 11C, a gate electrode layer 130 is formed on the gate insulating layer described above. The gate electrode layer 130 is then patterned to form a first electrode 131, a second electrode 132 and a gate electrode 133. The region where the first electrode 131 and the active layer 120 overlap is the first lap region 121A, the region where the second electrode 132 and the active layer 120 overlap is the second lap region 122A, and the region where the gate electrode 133 and the active layer 120 overlap is the channel region 123. The region between the first lap region 121A and the channel region 123 is the first transmission region 121B, and the region between the second lap region 122A and the channel region 123 is the second transmission region 122B. The first lap region 121A and the first transmission region 121B together constitute the first region 121. The second lap region 122A and the second transmission region 122B together constitute the second region 122.

As shown in FIG. 11C, the first electrode 131 and the first semi-doped region 191 partially overlap. In the second time of conductorization process performed on the active layer 120 by using the electrode layer 130 as a mask, a part of the first semi-doped region 191 not covered by the first electrode 131 undergoes one time of conductorization process and becomes part of the first transmission region 121B (a part located between two first arc-shaped conductive structures 141), a part of the first semi-doped region 191 covered by the first electrode 131 remains semi-doped and is formed as the first functional region 161. In such case, the part of the first semi-doped region 191 not covered by the first electrode 131 will not generate a loss or a partial loss because it has only undergone one time of complete conductorization process, and the part of the first doped region 151 not covered by the first electrode 131 will generate a loss or a partial loss after two times of conductorization processes to form two first arc-shaped conductive structures 141 spaced apart from each other, so that a plurality of stable conductive channels can be formed between the first lap region 121A and the first transmission region 121B, thereby enhancing the conductivity of the thin-film transistor.

It is to be noted that the above only describes the formation process of each structure in the first region with reference to FIGS. 11A-11C. It is understood that the second region can also have a structure similar or symmetrical to that of the first region, and the formation process of the second region can refer to the above description and will not be repeated here.

An embodiment of the present disclosure also provides another thin-film transistor. FIG. 12 is a schematic plan view of another thin-film transistor provided in an embodiment of the present disclosure. As shown in FIG. 12, the thin-film transistor 100 includes an active layer 120 and an electrode layer 130. The active layer 120 includes a channel region 123, as well as a first region 121 and a second region 122 located at two sides of the channel region 123 in a first direction X. That is to say, the first region 121, the channel region 123 and the second region 122 are arranged sequentially along the first direction X. The electrode layer 130 includes a gate electrode 133, a first electrode 131 and a second electrode 132. The first region 121 includes a first lap region 121A and a first transmission region 121B, an orthographic projection of the first electrode 131 on the active layer 120 overlaps with the first lap region 121A, the first transmission region 121B includes at least one arc-shaped conductive structure 140, the at least one arc-shaped conductive structure 140 includes a first arc-shaped conductive structure 141, the first lap region 121A includes a first edge 201, the first arc-shaped conductive structure 141 is connected to the first edge 201. A size of an orthographic projection of the first arc-shaped conductive structure 140 on the first edge 201 is smaller than a length of the first edge 201.

In the thin-film transistor provided in the embodiment of the present disclosure, since one edge of the first lap region is provided with a first arc-shaped conductive structure, a stable conductive channel can be formed between the first lap region and the first transmission region through the first arc-shaped conductive structure, thereby enhancing the conductivity of the thin-film transistor. Furthermore, since the size of the orthographic projection of the arc-shaped conductive structure on the edge is smaller than the length of the edge, the edge of the first lap region and the first transmission region can also form other conductive channels in addition to this arc-shaped conductive structure, such as other arc-shaped conductive structures, thereby increasing the number and quality of conductive channels between the first lap region and the first transmission region, thereby enhancing the conductivity of the thin-film transistor.

In some examples, as shown in FIG. 12, the first lap region 121A further includes a first strip-shaped conductive region 211 located at the first edge 201, and the first strip-shaped conductive region 211 and the first arc-shaped conductive structure 141 are disposed sequentially in a second direction. That is to say, in addition to the first arc-shaped conductive structure, the first edge of the first lap region and the first transmission region can also form a conductive channel through the first strip-shaped conductive region, thereby increasing the number and quality of conductive channels between the first lap region and the first transmission region, and enhancing the conductivity of the thin-film transistor.

It is to be noted that the first strip-shaped conductive region described above can be formed by reasonably designing the shape of the region of the active layer that is subjected to the first time of conductorization process, and a doped, protruding region may be disposed at an edge of the first doped region, and a length of the protruding region is smaller than a length of the edge of the first doped region. This protruding region does not overlap with the first electrode, so a first arc-shaped conductive structure is formed in the second time of conductorization process, and a part of the edge of the first doped region that is not connected to the protruding region is formed as the strip-shaped conductive region due to the conductorization process.

In some examples, as shown in FIG. 12, the second region 122 includes a second lap region 122A and a second transmission region 122B, an orthographic projection of the second electrode 132 on the active layer 120 overlaps with the second lap region 122A, the second transmission region 122B includes a fourth arc-shaped conductive structure 144, each fourth arc-shaped conductive structure 144 includes a fourth hollow part 144A and a fourth thinning portion 144B at least partially surrounding the fourth hollow part 144A. A thickness of the fourth thinning portion 144B is smaller than a thickness of the active layer 120 in the channel region 123. The second lap region 122B includes a fourth edge 204 extending along a third direction, the fourth edge 204 and an edge of the channel region 123 are disposed opposite to each other at an interval, the fourth arc-shaped conductive structure 144 is connected to the fourth edge 204, and a size of the fourth arc-shaped conductive structure 144 in the third direction is smaller than a length of the fourth edge 204, the third direction intersects with the first direction. Similar to the first region 121, the second lap region 122A further includes a second strip-shaped conductive region 212 located at the fourth edge 204, and the second strip-shaped conductive region 212 and the fourth arc-shaped conductive structure 144 are disposed sequentially in the third direction.

In the thin-film transistor provided in the embodiment of the present disclosure, since the fourth edge of the second lap region is provided with a fourth arc-shaped conductive structure, the second lap region and the second transmission region may form a stable conductive channel through the fourth arc-shaped conductive structure, thereby enhancing the conductivity of the thin-film transistor. Moreover, in addition to the fourth arc-shaped conductive structure, the fourth edge of the second lap region and the second transmission region can also form a conductive channel through the second strip-shaped conductive region, thereby increasing the number and quality of conductive channels between the second lap region and the second transmission region, and enhancing the conductivity of the thin-film transistor.

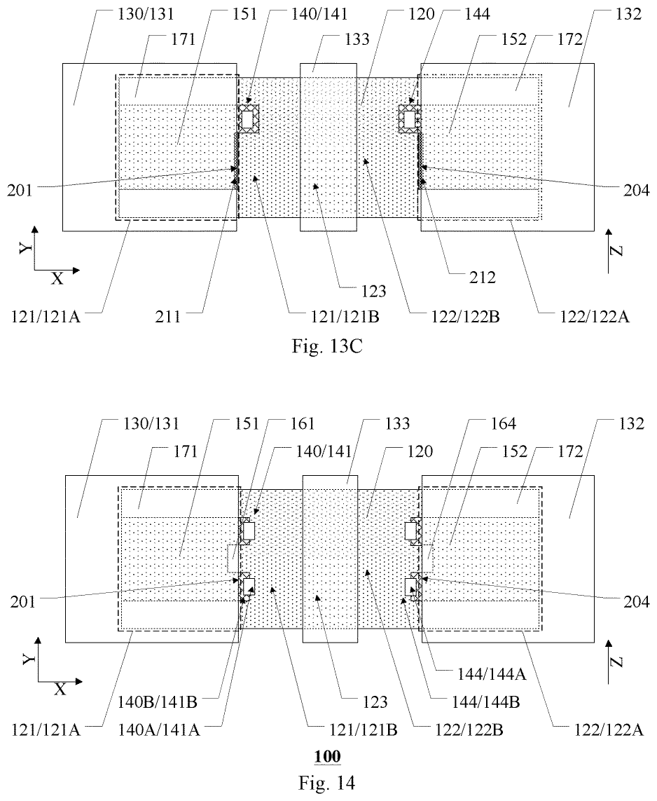

FIGS. 13A-13C are schematic diagrams illustrating steps of a manufacturing method of a thin-film transistor provided in an embodiment of the present disclosure.

As shown in FIG. 13A, a first doped region 151 and a protruding region 220 are formed on the active layer 120, the protruding region 220 is located at one edge of the first doped region 151 and is connected to the first doped region 151. A length of the protruding region 220 is smaller than a length of this edge. For example, a doping process can be performed on the active layer 120 by using the gate insulating layer on the active layer 120 as a mask, and a region exposed through an opening of the gate insulating layer is formed as the first doped region 151 and the protruding region 220 described above.

As shown in FIGS. 13B and 13C, a gate electrode layer 130 is formed on the gate insulating layer described above. The gate electrode layer 130 is then patterned to form a first electrode 131, a second electrode 132 and a gate electrode 133. The region where the first electrode 131 and the active layer 120 overlap is the first lap region 121A, the region where the second electrode 132 and the active layer 120 overlap is the second lap region 122A, and the region where the gate electrode 133 and the active layer 120 overlap is the channel region 123. The region between the first lap region 121A and the channel region 123 is the first transmission region 121B, and the region between the second lap region 122A and the channel region 123 is the second transmission region 122B. The first lap region 121A and the first transmission region 121B together constitute the first region 121. The second lap region 122A and the second transmission region 122B together constitute the second region 122.

As shown in FIG. 13C, the first electrode 131 overlaps with the first doped region 151, and the first electrode 131 and the protruding region 220 do not overlap. In the second time of conductorization process performed on the active layer 120 by using the electrode layer 130 as a mask, the protruding region 220 undergoes one time of conductorization process and becomes the first arc-shaped conductive structure 141; the first doped region 151 is covered by the first electrode 131, but a part of the edge of the first doped region 151 that is not provided with the protruding region 220 is conductorized and formed as the first strip-shaped conductive region 212, so that the first lap region 121A and the first transmission region 121B form a plurality of stable conductive channels, thereby enhancing the conductivity of the thin-film transistor.

It is to be noted that the above only describes the formation process of each structure in the first region with reference to FIGS. 13A-13C. It is understood that the second region can also have a structure similar or symmetrical to that of the first region, and the formation process of the second region can refer to the above description and will not be repeated here.

An embodiment of the present disclosure also provides another thin-film transistor. FIG. 14 is a schematic plan view of another thin-film transistor provided in an embodiment of the present disclosure. As shown in FIG. 14, the thin-film transistor 100 includes an active layer 120 and an electrode layer 130. The active layer 120 includes a channel region 123, as well as a first region 121 and a second region 122 located at two sides of the channel region 123 in a first direction X. The electrode layer 130 includes a gate electrode 133, a first electrode 131 and a second electrode 132. The first region 121 includes a first lap region 121A and a first transmission region 121B, an orthographic projection of the first electrode 131 on the active layer 120 overlaps with the first lap region 121A, the first transmission region 121B includes at least one arc-shaped conductive structure 140, each arc-shaped conductive structure 140 includes a hollow part 140A and a thinning portion 140B at least partially surrounding the hollow part 140A, a thickness of the thinning portion 140B is smaller than a thickness of the active layer 120 in the channel region 123. One arc-shaped conductive structure 140 is connected to one edge of the first lap region 121A. Unlike the thin-film transistor shown in FIG. 4A, the thinning portion 140 only partially surrounds the hollow part 140A, a plane shape of the thinning portion 140 is an arc shape or a C shape, and the thinning portion 140 is located at a side of the hollow part 140A close to the edge.

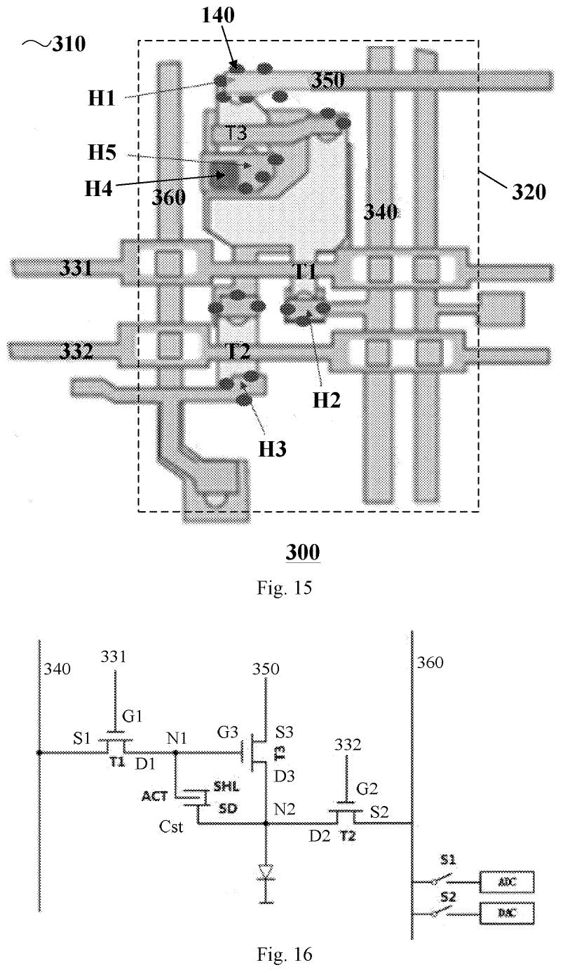

An embodiment of the present disclosure also provides an array substrate. FIG. 15 is a schematic plan view of an array substrate provided in an embodiment of the present disclosure; FIG. 16 is a schematic equivalent diagram of a pixel driving circuit in an array substrate provided in an embodiment of the present disclosure.

As shown in FIG. 15, the array substrate 300 includes a base substrate 310 and a plurality of pixel driving circuit 320 located on the base substrate 310. At least one pixel driving circuit 320 includes a thin-film transistor 100. Therefore, because the array substrate uses thin-film transistors with better conductivity and yield, it can also achieve better performance and yield.

In some examples, as shown in FIGS. 15-16, each pixel driving circuit 320 includes a first transistor T1, a second transistor T2 and a third transistor T3. The first transistor T1 includes a gate electrode G1, a first electrode S1, and a second electrode D1. The second transistor T2 includes a gate electrode G2, a first electrode S2 and a second electrode D2. The third transistor T3 includes a gate electrode G3, a first electrode S3, and a second electrode D3. The gate electrode G1 of the first transistor T1 is configured to be connected to a first gate line 331, the first electrode S1 of the first transistor T1 is configured to be connected to a data line 340, and the second electrode D1 of the first transistor T1 is connected to the gate electrode G3 of the third transistor T3. The first electrode S3 of the third transistor T3 is configured to be connected to a power line 350, the gate electrode G2 of the second transistor T2 is configured to be connected to a second gate line 332, the first electrode S2 of the second transistor T2 is configured to be connected to a sensing line 360, and the second electrode D2 of the second transistor T2 is connected to the second electrode D3 of the third transistor T3.

In some examples, as shown in FIGS. 15-16, the first transistor T1, the second transistor T2 and the third transistor T3 all adopt the thin-film transistor 100 described above. Further, the number of the arc-shaped conductive structures 140 in the third transistor T3 is greater than the number of the arc-shaped conductive structure(s) 140 in the second transistor T2, and is also greater than the number of the arc-conductive structure(s) 140 in the first transistor T1. In the array substrate, since the third transistor T3 is a driving transistor, the driving capability of the driving transistor can be improved by raising the conductive capability of the third transistor through increasing the number of the arc-shaped conductive structures in the third transistor.

In some examples, as shown in FIGS. 15-16, the first electrode S3 of the third transistor T3 is connected to the active layer 120 of the third transistor T3 through a first via hole H1, the first electrode S1 of the first transistor T1 is connected to the active layer 120 of the first transistor T1 through a second via hole H2, and the first electrode S2 of the second transistor T2 is connected to the active layer 120 of the second transistor T2 through a third via hole H3. An area of an orthographic projection of the first via hole H1 on the base substrate 310 is greater than an area of an orthographic projection of the second via hole H2 on the base substrate 310, and is also greater than an area of an orthographic projection of the third via hole H3 on the base substrate 310. As a result, the third transistor T3 has a strong driving capability, which can improve the electrical performance of the array substrate. It is to be noted that the first electrode S3 of the third transistor T3 may be a part of the power line 350.

In some examples, as shown in FIG. 15, a size of the orthographic projection of the first via hole H1 on the base substrate 310 in an extension direction of the first gate line 331 is greater than a size of the channel region 123 of the active layer 120 of the third transistor T3 in an extension direction of the first gate line 331, so that more arc-shaped conductive structures can be provided at two sides of the power line while ensuring the aperture ratio, thereby improving the conductive performance of the drive transistor.

In some examples, as shown in FIG. 15, an size of the first via hole H1 on the base substrate 310 in an extension direction of the data line 340 is smaller than a size of the channel region 123 of the active layer 120 of the third transistor T3 in an extension direction of the data line 340, thereby increasing the aperture ratio.

In some examples, as shown in FIG. 15, the array substrate 300 further includes an anode 360, the anode 360 is electrically connected to the second electrode D3 of the third transistor T3 through a fourth via hole H4. The area of the orthographic projection of the first via hole H1 on the base substrate 310 is greater than an area of an orthographic projection of the fourth via hole H4 on the base substrate 310.

In some examples, as shown in FIG. 15, the second electrode D3 of the third transistor T3 is connected to the active layer 120 of the third transistor T3 through a fifth via hole H4. An aspect ratio of the orthographic projection of the first via hole H1 on the base substrate 310 is greater than an aspect ratio of an orthographic projection of the fifth via hole H5 on the base substrate 310.

In some examples, each pixel driving circuit 320 further includes a storage capacitor Cst, the storage capacitance Cst includes a first electrode ACT located in the active layer, a second electrode SHL located in a light-shielding layer, and a third electrode SD located in a source-drain metal layer or the gate electrode layer described above; the second electrode SHL and the third pole SD are electrically connected to form an interlayer capacitor together with the first electrode ACT. The first electrode ACT, the second electrode D2 of the first transistor T1 and the gate electrode G3 of the third transistor T3 are connected to a first node N1. The second electrode D3 of the third transistor T3, the second electrode SHL, the third electrode SD, a first electrode of a light-emitting element, and the second electrode D2 of the second transistor T2 are connected to a second node N2.

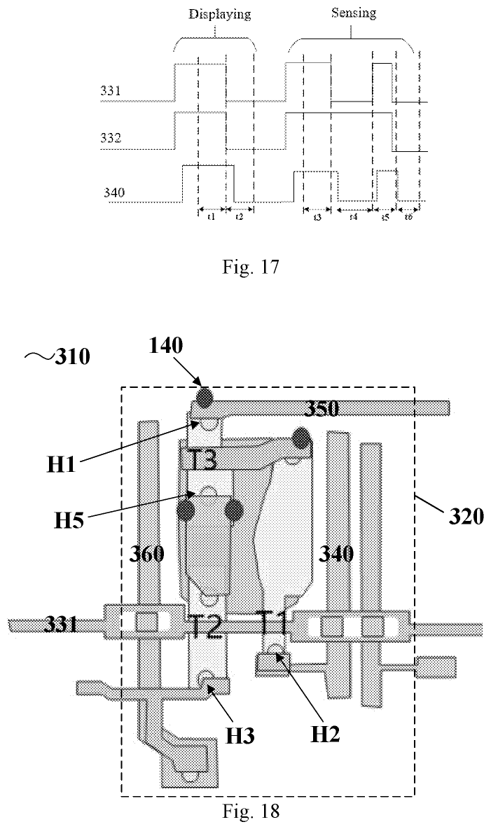

FIG. 17 is a driving timing diagram of a pixel driving circuit in an array substrate provided in an embodiment of the present disclosure.

Referring to FIG. 17, in a first stage t1, a first control signal on the first gate line 331 and a second control signal on the second gate line 332 are both turn-on signals, the first transistor T1 and the second transistor T2 are turned on, a data signal is transmitted to the gate electrode of the third transistor T3 via the second transistor T1 through the data line 340, and the third transistor T3 is turned on, a reset signal Vint is written into a first driving electrode of the light-emitting element (such as an anode of an OLED) by a sensing signal through the sensing line 360 and the second transistor T2.

In a second stage t2, the first control signal on the first gate line 331 and the second control signal on the second gate line 332 are both turn-off signals, a voltage across the storage capacitor Cst remains unchanged, the third transistor T3 operates in a saturated state with the current unchanged and drives the light-emitting element to emit light.

If the present row of pixels need to be compensated, a sensing stage t3-t6 is entered.

In a third stage t3, the first control signal on the first gate line 331 and the second control signal on the second gate line 332 are both turn-on signals, the first transistor T1 and the second transistor T2 are turned on, the data signal is transmitted through the first transistor T1 to the gate electrode of the third transistor T3, the third transistor T3 is turned on, and the reset signal Vint is written into the first electrode of the light-emitting element (such as the anode of the OLED) by the sensing signal through the second transistor T2.

In a fourth stage t4, the first transistor T1 is turned off, the second transistor T2 and the third transistor T3 are turned on, the second node N2 discharges to a parasitic capacitance on the sensing line until the third transistor T3 satisfies Vgs=Vth, the third transistor T3 is turned off; at this time, a sensing IC obtains a potential of the second node N2, so that the Vth of the third transistor T3 can be calculated, and characteristic parameters of the third transistor T3 such as the mobility can also be calculated according to the discharge curve of the second node N2.

In a fifth stage t5, the first transistor T1 is turned on, the data line writes a data voltage into the gate electrode of the third transistor T3. Since the present row of pixels do not emit light in the sensing stage, a dark line will be generated. Therefore, a data voltage is immediately written back after the fourth stage to enable the present row of pixels to emit light, which reduces the influence on the display effect resulted by the dark line.

In a sixth stage t6, the first transistor T1 and the second transistor T2 are turned off, and the light-emitting element emits light.

It is to be noted that the fifth stage T5 and the sixth stage T6 are timing sequences added for power-on compensation, and these two stages are not required for shutdown compensation.

An embodiment of the present disclosure also provides an array substrate. FIG. 18 is a schematic plan view of an array substrate provided in an embodiment of the present disclosure.

As shown in FIG. 18, the array substrate 300 includes a base substrate 310 and a plurality of pixel driving circuits 320 located on the base substrate 310. At least one pixel driving circuit 320 includes a thin-film transistor 100. Therefore, because the array substrate uses thin-film transistors with better conductivity and yield, it can also achieve better performance and yield.

In some examples, as shown in FIG. 18, each pixel driving circuit 320 includes a first transistor T1, a second transistor T2 and a third transistor T3. A gate electrode of the first transistor T1 is configured to be connected to a first gate line 331, a first electrode of the first transistor T1 is configured to be connected to a data line 340, and a second electrode of the first transistor T1 is connected to a gate electrode of the third transistor T3. A first electrode of the third transistor T3 is configured to be connected to a power line 350, a gate electrode of the second transistor T2 is configured to be connected to the first gate line 331, a first electrode of the second transistor T2 is configured to be connected to a sensing line 360, and a second electrode of the second transistor T2 is connected to the second electrode of the third transistor T3. In this example, the gate electrode of the first transistor T1 and the gate electrode of the second transistor T2 share the first gate line 331.

In some examples, as shown in FIG. 18, the first transistor T1, the second transistor T2 and the third transistor T3 all adopt the thin-film transistor 100 described above.

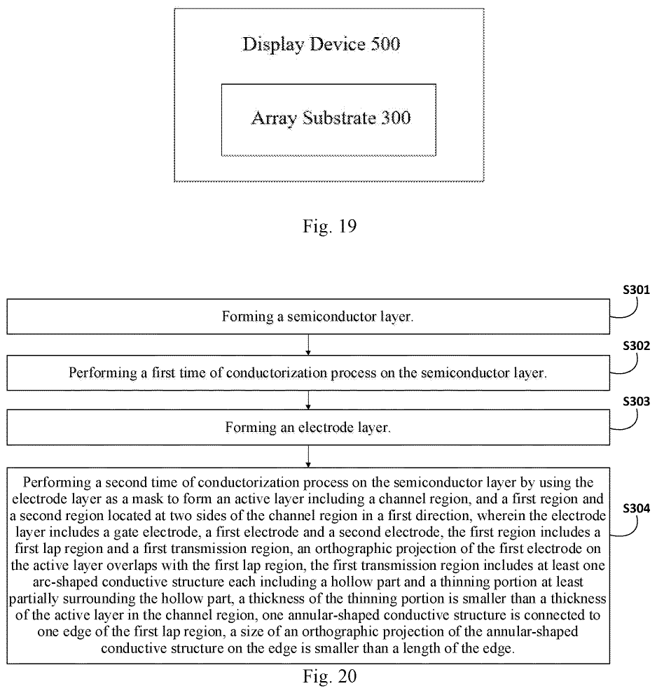

An embodiment of the present disclosure also provides a display device. FIG. 19 is a schematic diagram of a display device provided in an embodiment of the present disclosure. As shown in FIG. 19, the display device 500 includes the array substrate 300 described above. Since the display device includes an array substrate with strong driving capability, high yield and high aperture ratio, it also achieves the advantages of strong driving capability, high yield and high aperture ratio.

In some examples, the display device may be a notebook computer, a television, a navigator, an electronic photo album, a tablet computer and other electronic products with display functions.

An embodiment of the present disclosure also provides a manufacturing method of a thin-film transistor. FIG. 20 is a flow chart of a manufacturing method of a thin-film transistor provided in an embodiment of the present disclosure. As shown in FIG. 20, the manufacturing method of the thin-film transistor includes the following steps S301-S304.

Step S301: forming a semiconductor layer.

For example, a material of the semiconductor layer can be polysilicon, monocrystalline silicon, oxide semiconductor and other semiconductor materials.

Step S302: performing a first time of conductorization process on the semiconductor layer.

For example, a first time of semiconductorization process can be carried out by using a gate insulating layer on the semiconductor layer as a mask, the specific process may refer to the description in the relevant examples of other embodiments described above, and will not be repeated here.

Step S303: forming an electrode layer.

For example, the electrode layer may include a gate electrode, a first electrode, and a second electrode. One of the first and second electrodes is a source electrode and the other one is a drain electrode.

Step S304: performing a second time of conductorization process on the semiconductor layer by using the electrode layer as a mask to form an active layer including a channel region as well as a first region and a second region located at two sides of the channel region in a first direction. The electrode layer includes a gate electrode, a first electrode and a second electrode, the first region includes a first lap region and a first transmission region, an orthographic projection of the first electrode on the active layer overlaps with the first lap region, the first transmission region includes at least one arc-shaped conductive structure, each arc-shaped conductive structure includes a hollow part and a thinning portion at least partially surrounding the hollow part, a thickness of the thinning portion is smaller than a thickness of the active layer in the channel region, one arc-shaped conductive structure is connected to one edge of the first lap region, a size of an orthographic projection of the arc-shaped conductive structure on the edge is smaller than a length of the edge, and the thinning portion is located at a side of the hollow part close to the edge.

In the manufacturing method of the thin-film transistor provided in the embodiment of the present disclosure, since one edge of the first lap region is provided with an arc-shaped conductive structure, a stable conductive channel can be formed between the first lap region and the first transmission region through the arc-shaped conductive structure, thereby enhancing the conductivity of the thin-film transistor. Moreover, since the size of the orthographic projection of the arc-shaped conductive structure on the edge is smaller than the length of the edge, the edge of the first lap region and the first transmission region can also form other conductive channels in addition to this arc-shaped conductive structure, such as other arc-shaped conductive structures, thereby increasing the number and quality of conductive channels between the first lap region and the first transmission region, and enhancing the conductivity of the thin-film transistor.

The following points need to be explained:
(1) In the drawings of the embodiments of the present disclosure, only the structure related to the embodiments of the present disclosure is involved, and other structures can refer to the general design.
(2) Features in the same embodiment and different embodiments of the present disclosure can be combined with each other without conflict.

The above is merely the specific embodiments of the present disclosure, which is not intended to limit the scope of protection of the present disclosure thereto. Any person familiar with the technical field can easily conceive of changes or substitutions within the technical scope disclosed in the present disclosure, which should be included in the scope of protection of the present disclosure. Therefore, the scope of protection of the present disclosure should be based on the scope of protection of the claims.

What is claimed is:

1. A thin-film transistor, comprising:
an active layer comprising a channel region, and a first region and a second region located at two sides of the channel region in a first direction;
a gate insulating layer; and
an electrode layer comprising a gate electrode, a first electrode, and a second electrode,
wherein the first region comprises a first lap region and a first transmission region, the first lap region is in contact with the first electrode or the second electrode, and the first lap region comprises a first doped region and a first functional region, wherein a thickness of the first functional region is greater than a thickness of the first doped region.

2. The thin-film transistor according to claim 1, wherein the first functional region is located at a side of the first doped region close to the gate electrode.

3. The thin-film transistor according to claim 1, wherein the gate insulating layer at least partially covers the first transmission region.

4. The thin-film transistor according to claim 1, wherein the first functional region is a semi-doped region.

5. The thin-film transistor according to claim 1, wherein a planar shape of the first functional region is a rectangular shape.

6. The thin-film transistor according to claim 1, wherein the first functional region comprises a first side edge away from the gate electrode and a second side edge close to the gate electrode.

7. The thin-film transistor according to claim 6, wherein the first side edge of the first functional region is connected to the first doped region, and the second side edge of the first functional region is connected to the first transmission region.

8. The thin-film transistor according to claim 1, wherein a contour of the first functional region is surrounded by the first doped region and the first transmission region.

9. The thin-film transistor according to claim 1, wherein the thickness of the first functional region is greater than a thickness of part of the first transmission region.

10. The thin-film transistor according to claim 1, wherein an orthographic projection of the gate electrode on the active layer is located in the channel region, the first electrode is a source electrode, and the second electrode is a drain electrode.

11. The thin-film transistor according to claim 1, wherein an area of the first functional region is smaller than an area of the channel region.

12. The thin-film transistor according to claim 1, wherein the active layer further comprises a first thinning portion located between the first functional region and the gate electrode.

13. The thin-film transistor according to claim 12, wherein an area of the first functional region is smaller than an area of the first thinning portion.

14. The thin-film transistor according to claim 1, wherein the first lap region further comprises a first semiconductor region located at two sides of the first doped region in a second direction, an area of the first functional region is smaller than an area of the first semiconductor region, and the second direction intersects the first direction.

15. The thin-film transistor according to claim 1, wherein the first transmission region comprises at least one arc-shaped conductive structure, each arc-shaped conductive structure comprises a hollow part and a thinning portion at least partially surrounding the hollow part, a thickness of the thinning portion is smaller than a thickness of the active layer in the channel region; and
one arc-shaped conductive structure is connected to an edge of the first lap region, a size of an orthographic projection of the arc-shaped conductive structure on the edge is smaller than a length of the edge, and the thinning portion is located at a side of the hollow part close to the edge.

16. The thin-film transistor according to claim 15, wherein the at least one arc-shaped conductive structure comprises a first arc-shaped conductive structure, the first arc-shaped conductive structure comprises a first hollow part and a first thinning portion at least partially surrounding the first hollow part, a thickness of the first thinning portion is smaller than the thickness of the active layer in the channel region; and
the first lap region comprises a first edge extending in a second direction, the first edge is opposite to and spaced apart from an edge of the channel region, the first arc-shaped conductive structure is connected to the first edge, and a size of the first arc-shaped conductive structure in the second direction is smaller than a length of the first edge, wherein the second direction intersects the first direction.

17. The thin-film transistor according to claim 16, wherein the at least one arc-shaped conductive structure comprises at least two first arc-shaped conductive structures, and the first functional region is connected to the first edge and located between two first arc-shaped conductive structures in the second direction.

18. The thin-film transistor according to claim 17, wherein the at least one arc-shaped conductive structure further comprises at least two second arc-shaped conductive structures, each second arc-shaped conductive structure comprises a second hollow part and a second thinning portion at least partially surrounding the second hollow part, a thickness of the second thinning portion is smaller than the thickness of the active layer in the channel region; and
the first lap region further comprises a second edge connected to the first edge, the first lap region further comprises a second functional region connected to the second edge and located between two second arc-shaped conductive structures in the first direction, the second arc-shaped conductive structure is connected to the second edge, and a size of the second arc-shaped conductive structure in the first direction is smaller than a length of the second edge.

19. The thin-film transistor according to claim 18, wherein the at least one arc-shaped conductive structure further comprises at least two third arc-shaped conductive structures, each third arc-shaped conductive structure comprises a third hollow part and a third thinning portion at least partially surrounding the third hollow part, a thickness of the third thinning portion is smaller than the thickness of the active layer in the channel region; and
the first lap region further comprises a third edge connected to the first edge, the third edge is opposite to and spaced apart from the second edge, the first lap region further comprises a third functional region connected to the third edge and located between two third arc-shaped conductive structures in the first direction, the third arc-shaped conductive structure is connected to the third edge, and a size of the third arc-shaped conductive structure in the first direction is smaller than a length of the third edge.

20. An array substrate, comprising:
a base substrate; and
a plurality of pixel driving circuits located on the base substrate,
wherein at least one pixel driving circuit comprises the thin-film transistor according to claim 1.

21. The array substrate according to claim 20, wherein each pixel driving circuit comprises:
a first transistor comprising a gate electrode, a first electrode and a second electrode;
a second transistor comprising a gate electrode, a first electrode and a second electrode;
a third transistor comprising a gate electrode, a first electrode and a second electrode,
wherein the gate electrode of the first transistor is configured to be connected to a first gate line, the first electrode of the first transistor is configured to be connected to a data line, the second electrode of the first transistor is connected to the gate electrode of the third transistor; and
the first electrode of the third transistor is configured to be connected to a power line, the gate electrode of the second transistor is configured to be connected to a second gate line, the first electrode of the second transistor is configured to be connected to a sensing line, and the second electrode of the second transistor is connected to the second electrode of the third transistor.

22. The array substrate according to claim 21, wherein each of the first transistor, the second transistor and the third transistor is the thin-film transistor;
the first transmission region comprises at least one arc-shaped conductive structure, each arc-shaped conductive structure comprises a hollow part and a thinning portion at least partially surrounding the hollow part, a thickness of the thinning portion is smaller than a thickness of the active layer in the channel region; and
one arc-shaped conductive structure is connected to an edge of the first lap region, a size of an orthographic projection of the arc-shaped conductive structure on the edge is smaller than a length of the edge, and the thinning portion is located at a side of the hollow part close to the edge,
wherein a number of the arc-shaped conductive structures in the third transistor is greater than a number of the arc-shaped conductive structures in the second transistor, and is greater than a number of the arc-shaped conductive structures in the first transistor.

23. The array substrate according to claim 22, wherein the first electrode of the third transistor is connected to the active layer of the third transistor through a first via hole, the first electrode of the first transistor is connected to the active layer of the first transistor through a second via hole, and the first electrode of the second transistor is connected to the active layer of the second transistor through a third via hole; and
an area of an orthographic projection of the first via hole on the base substrate is larger than an area of an orthographic projection of the second via hole on the base substrate, and is larger than an area of an orthographic projection of the third via hole on the base substrate.

24. A display device, comprising the array substrate according to claim 20.
